(19) United States
(12) Patent Application Publication
(10) Pub. No.: US 2026/0052849 A1
(43) Pub. Date: Feb. 19, 2026

(54) DISPLAY PANEL AND ELECTRONIC DEVICE INCLUDING THE SAME

(71) Applicant: Samsung Display Co., Ltd., Yongin-si (KR)

(72) Inventors: JEONGJU PARK, Yongin-si (KR); YEEUN KANG, Yongin-si (KR); ILBAE AHN, Yongin-si (KR); HANHEE YOON, Yongin-si (KR); WOOGEUN LEE, Yongin-si (KR); JIN-WON LEE, Yongin-si (KR)

(21) Appl. No.: 19/289,514

(22) Filed: Aug. 4, 2025

(30) Foreign Application Priority Data
Aug. 19, 2024 (KR) 10-2024-0110421

(51) Int. Cl. H10K 59/122; H10K 59/80

(52) U.S. Cl. CPC H10K 59/122; H10K 59/8792

(57) ABSTRACT

A display panel includes a base substrate, a circuit layer including a transistor, a pixel-defining layer defining an emission opening portion, an auxiliary layer including a transparent metal oxide, a separator including a black component, and having an edge protruding toward the emission opening portion further than an edge of the auxiliary layer, and a light-emitting element above the circuit layer, and including a first electrode in the emission opening portion, a second electrode facing the first electrode, emission structures between the first electrode and the second electrode, and charge generation layers between the first electrode and the second electrode, wherein a stepped space is defined by a portion of a bottom surface of the separator, the edge of the auxiliary layer, and a portion of an upper surface of the pixel-defining layer, and wherein at least one of the charge generation layers is disconnected at the stepped space.

### CROSS-REFERENCE TO RELATED APPLICATION

The present application claims priority to, and the benefit of, Korean Patent

Application No. 10-2024-0110421, filed on Aug. 19, 2024, in the Korean Intellectual Property Office, the entire disclosure of that is incorporated by reference.

### BACKGROUND

The present disclosure herein relates to a display panel including a light-emitting element including a functional layer provided, in common, to adjacent emission areas, and an electronic device including the display panel.

Multimedia electronic devices, such as televisions, mobile phones, tablet computers, navigation devices, game consoles, or wearable devices, may include display panels that display images. A display panel uses a so-called self-emissive display element that accomplishes display by allowing a light-emitting material including an organic compound, a quantum dot, or the like in an emission layer located between electrodes facing each other to emit light.

In addition, as a demand for high definition of the multimedia electronic devices increases, an arrangement gap between adjacent light-emitting elements is decreased so as to exhibit high-resolution display quality, which may lead to a phenomenon in which leakage emission affecting luminous characteristics of an adjacent pixel may be generated to decrease the display quality.

### SUMMARY

The present disclosure provides a display panel having excellent display quality and high resolution, and an electronic device including the display panel.

One or more embodiments of the present disclosure provides a display panel including a base substrate, a circuit layer above the base substrate, and including a transistor, a pixel-defining layer above the circuit layer, and defining an emission opening portion, an auxiliary layer above the pixel-defining layer, and including a transparent metal oxide, a separator above the auxiliary layer, including a black component, and having an edge protruding toward the emission opening portion further than an edge of the auxiliary layer, and a light-emitting element above the circuit layer, and including a first electrode in the emission opening portion, a second electrode facing the first electrode, emission structures between the first electrode and the second electrode, and charge generation layers between the first electrode and the second electrode, wherein a stepped space is defined by a portion of a bottom surface of the separator, the edge of the auxiliary layer, and a portion of an upper surface of the pixel-defining layer, and wherein at least one of the charge generation layers is disconnected at the stepped space.

The display panel may further include an air pocket in the stepped space at which the emission structures and the charge generation layers are discontinuous.

The at least one of the charge generation layers may include one end above the pixel-defining layer, and another end above the separator.

The emission structures may include a first emission structure, a second emission structure, a third emission structure, and a fourth emission structure, stacked in a thickness direction and including an emission layer, wherein the charge generation layers include a first charge generation layer between the first emission structure and the second emission structure, a second charge generation layer between the second emission structure and the third emission structure, and a third charge generation layer between the third emission structure and the fourth emission structure, and wherein at least one of the first emission structure, the second emission structure, the third emission structure, or the fourth emission structure and at least one of the first charge generation layer, the second charge generation layer, or the third charge generation layer are disconnected at the stepped space.

The separator may include an organic film including a black component.

The separator may overlap only a partial area of the pixel-defining layer.

The auxiliary layer may include a transparent conductive oxide material that is crystallized at a temperature of about 260° C. or more, and an indium gallium zinc oxide (IGZO) or an indium zinc oxide (IZO) having a weight ratio of indium to zinc of about 9:1 to about 1:1.

A thickness of the auxiliary layer may be about 100 Å to about 1000 Å.

A tilt angle of a side surface of the separator to the base substrate may be about 50 degrees to about 90 degrees.

The transistor may include a semiconductor pattern including a metal oxide

including at least one of indium, gallium, zinc, tin, or titanium divided into an active, a source, and a drain, and a gate above the semiconductor pattern.

In one or more embodiments of the present disclosure, a display panel includes a base substrate, a circuit layer above the base substrate, and including a transistor, and a display layer above the circuit layer, defining emission areas separated from each other, and including a pixel-defining layer above the circuit layer, and defining an emission opening portion corresponding to the emission areas, an auxiliary layer above the pixel-defining layer, and including a transparent metal oxide, a separator above the auxiliary layer, including a black component, and having an edge protruding further toward the emission opening portion than an edge of the auxiliary layer, and a light-emitting element above the circuit layer, and including a first electrode, a second electrode facing the first electrode, emission structures between the first electrode and the second electrode, and charge generation layers between the first electrode and the second electrode, wherein a stepped space having an undercut shape is defined by a portion of a bottom surface of the separator, the edge of the auxiliary layer, and a portion of an upper surface of the pixel-defining layer, and wherein at least one of the charge generation layers is disconnected at the stepped space.

On a plane, the emission areas may have a polygonal shape having a short side extending in a first direction, and a long side extending in a second direction crossing the first direction, wherein the separator has a shape extending in the second direction between adjacent ones of the emission areas adjacent to each other in the first direction, and includes a main portion between the adjacent ones of the emission areas, a secondary portion spaced apart from the main portion, and spaced apart from at least one of the adjacent ones of the emission areas in the second direction, or a bending portion having a shape surrounding at least a portion of a corner of the at least one of the adjacent ones of the emission areas.

The separator may include an organic film including a black component.

The auxiliary layer may include an indium zinc oxide having a weight ratio of indium to zinc of about 9:1 to about 1:1.

The emission structures may include at least one green emission structure and at least one blue emission structure.

In one or more embodiments of the present disclosure, an electronic device includes a display panel including a first emission area, a second emission area, and a third emission area spaced apart on a plane, sequentially arranged in a first direction, and configured to emit source light, and a light control panel above the display panel, and configured to transmit the source light or to convert a wavelength of the source light, wherein the display panel includes a base substrate, a circuit layer above the base substrate, and including a transistor, a pixel-defining layer above the circuit layer, and defining an emission opening portion, an auxiliary layer above the pixel-defining layer, and including a transparent metal oxide, a separator above the auxiliary layer, including a black component, and having an edge protruding further toward the emission opening portion than an edge of the auxiliary layer, and a light-emitting element above the circuit layer, and including a first electrode in the emission opening portion, a second electrode facing the first electrode, emission structures between the first electrode and the second electrode, and charge generation layers between the first electrode and the second electrode, wherein a stepped space is defined by a portion of a bottom surface of the separator, the edge of the auxiliary layer, and a portion of an upper surface of the pixel-defining layer, and wherein at least one of the charge generation layers is disconnected at the stepped space.

The electronic device may further comprise at least one of a processor, a memory, or a power module.

The electronic device may be an image display device, a wearable device, or a device for vehicle.

The electronic device may further include an air pocket in the stepped space at which the emission structures and the charge generation layers are discontinuous, wherein the at least one of the charge generation layers includes one end above the pixel-defining layer, and another end above the separator.

The separator may include an organic film including a black component, wherein the separator is provided in plural to be respectively in spaces respectively between the first emission area and the second emission area, and between the second emission area and the third emission area.

The auxiliary layer may include an indium zinc oxide having a weight ratio of indium to zinc of about 9:1 to about 1:1.

The electronic device may further include a first pixel area, a second pixel area, and a third pixel area, wherein the light control panel includes a light control layer including a light control part and a division pattern defining a first division opening portion corresponding to the first pixel area, a second division opening portion corresponding to the second pixel area, and a third division opening portion corresponding to the third pixel area, and a color filter layer above the light control layer, and including a first color filter, a second color filter, and a third color filter, wherein the light control part includes a first light control part in the first division opening portion, corresponding to the first color filter, and including a first quantum dot, a second light control part in the second division opening portion, corresponding to the second color filter, and including a second quantum dot, and a third light control part in the third division opening portion, corresponding to the third color filter, and including a third quantum dot, wherein the first pixel area, the second pixel area, and the third pixel area emit light in different respective wavelength regions, and wherein the separator is provided as a plurality of separators respectively corresponding to spaces respectively between the first pixel area and the second pixel area, and between the second pixel area and the third pixel area.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain aspects of the present disclosure. In the drawings:

FIG. 1 is a perspective view of an electronic device according to one or more embodiments;

FIG. 2A is a perspective view of a display module according to one or more embodiments;

FIG. 2B is a cross-sectional view of a display module according to one or more embodiments;

FIG. 2C is a plan view of a display module according to one or more embodiments;

FIG. 3 is an enlarged plan view of a portion of a display module according to one or more embodiments;

FIG. 4 is a cross-sectional view of a portion of a display module according to one or more embodiments;

FIGS. 5A to 5C are each a cross-sectional view of a display module according to one or more embodiments;

FIG. 6 is a cross-sectional view of a light-emitting element according to one or more embodiments;

FIG. 7 is a cross-sectional view of a portion of a display panel according to one or more embodiments;

FIG. 8 is a cross-sectional view of a portion of a display panel according to one or more embodiments;

FIG. 9A is a cross-sectional view of a portion of a display panel according to one or more embodiments;

FIG. 9B is a cross-sectional view of a portion of a display panel according to one or more embodiments;

FIG. 10A is a plan view of a portion of a display panel according to one or more embodiments;

FIG. 10B is a plan view of a portion of a display panel according to one or more embodiments; and

FIGS. 11A to 11D are each a view illustrating one operation of a method for manufacturing a display panel according to one or more embodiments.

FIG. 12 is a block diagram of an electronic device according to an embodiment;

FIG. 13 illustrates schematic views of an electronic device according to an embodiment;

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, a display panel according to one or more embodiments and an electronic device according to one or more embodiments will be described with reference to the accompanying drawings.

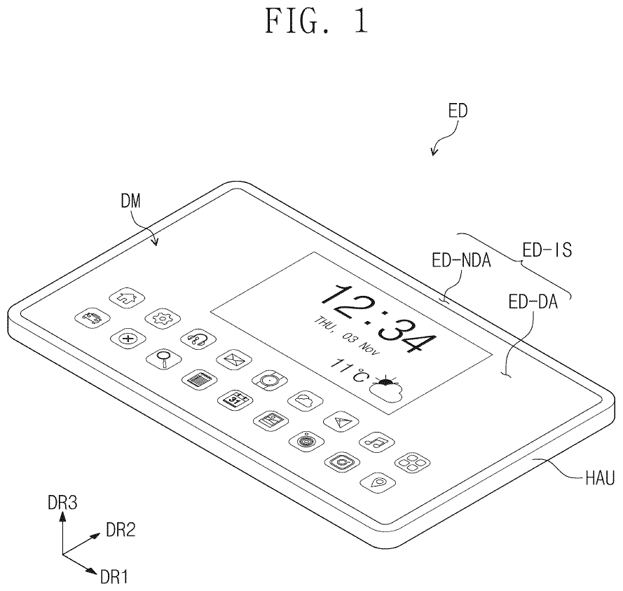

FIG. 1 is a perspective view of an electronic device ED according to one or more embodiments of the present disclosure. As illustrated in FIG. 1, the electronic device ED may include a display module DM which displays an image through a display surface ED-IS. The display module DM may be accommodated and located in a housing HAU.

The display surface ED-IS of the electronic device ED may have a rectangular shape having long sides extending in a first direction DR1, and short sides extending in a second direction DR2 crossing the first direction DR1 in plan view/when viewed on a plane. However, one or more embodiments of the present disclosure is not limited thereto, and the display surface ED-IS may have various shapes, such as a circular shape and a polygonal shape.

In the present disclosure, a third direction DR3 may be defined as a direction substantially perpendicular to a plane defined by the first direction DR1 and the second direction DR2. A front surface (or top surface) and a rear surface (or bottom surface) of each member, which constitutes the electronic device ED, may oppose each other in the third direction DR3, and a normal direction to each of the front surface and the rear surface may be substantially parallel to the third direction DR3. A separation distance between the front surface and the rear surface, which is defined in the third direction DR3, may correspond to a thickness of the member.

The term “on a plane” used herein may be defined as being in a state when viewed in the third direction DR3. That is, “on a plane” may be described on the basis of a plane defined by the first direction DR1 and the second direction DR2 together. The term “on a cross-section” used herein may be defined as being in a state as viewed in the first direction DR1 or the second direction DR2. Meanwhile, directions indicated by the first to third directions DR1, DR2 and DR3 are relative concepts and may be changed to other directions.

In one or more embodiments, the electronic device ED is illustrated as one having a flat display surface and including the display module DM, but is not limited thereto. Alternatively, the electronic device ED may include a curved display surface or a three-dimensional display surface. For example, the three-dimensional display surface may include a plurality of display areas oriented in different directions and may include a bent display surface. The electronic device ED may be a flexible electronic device. The flexible electronic device may be a foldable electronic device.

FIG. 1 and the like illustrate a tablet terminal as an example of the electronic device ED. Electronic modules, a camera module, a power module, and the like, which are mounted on a main board, may be located in a bracket/case or the like together with the display module DM, thereby constituting the tablet terminal. However, one or more embodiments is not limited thereto, and the display module DD may apply to a large-sized electronic device, such as a television or a monitor, and also to a small- and medium-sized electronic device, such as a mobile phone, a vehicle navigation device, a game console, or a smart watch. The electronic device ED including the display module DM may be also referred to as a display device.

As illustrated in FIG. 1, the display surface ED-IS includes an active area ED-DA on which an image is displayed, and a bezel area ED-NDA adjacent to the active area ED-DA. The bezel area ED-NDA is an area on which an image is not displayed. FIG. 1 illustrates icon images as one example of the image. The active area ED-DA may be referred to as a display area of the display module DM, and the bezel area ED-NDA may be referred to as a non-display area of the display module DM.

As illustrated in FIG. 1, the active area ED-DA may have a substantially rectangular shape. The “substantially rectangular shape” includes not only a rectangular shape in terms of mathematics, but also a rectangular shape in which not a vertex but a curved boundary is defined on a vertex area (or corner area).

The bezel area ED-NDA may surround the active area ED-DA (e.g., in plan view). However, one or more embodiments of the present disclosure is not limited thereto, and a shape of the bezel area ED-NDA may be changed. For example, the bezel area ED-NDA may be located at only one side of the active area ED-DA.

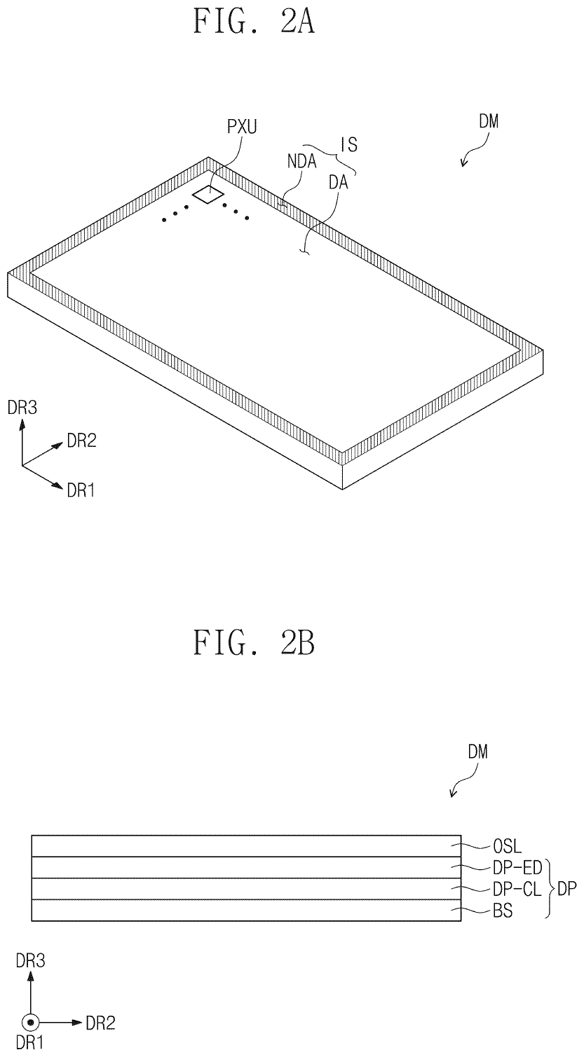

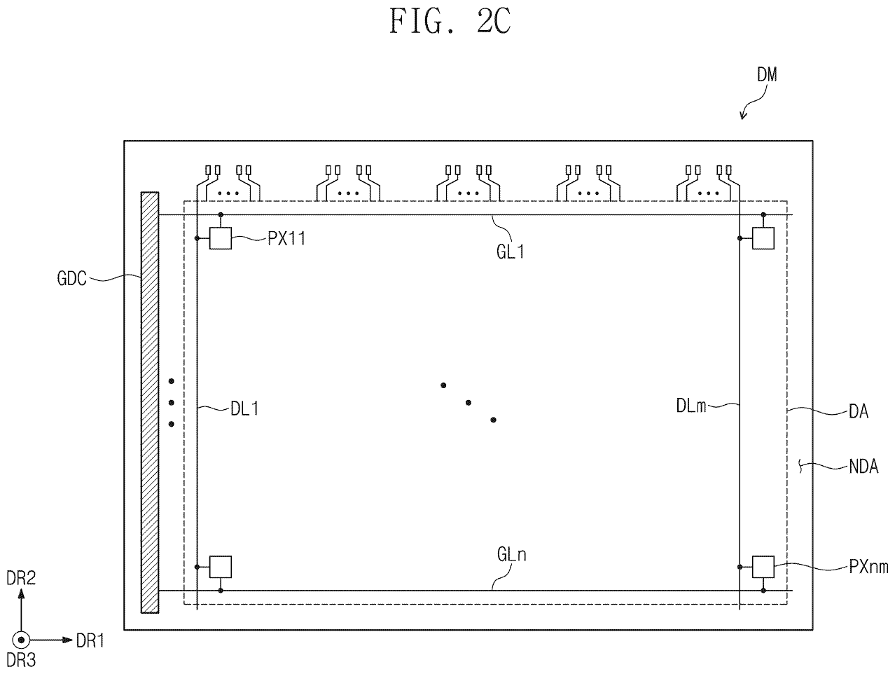

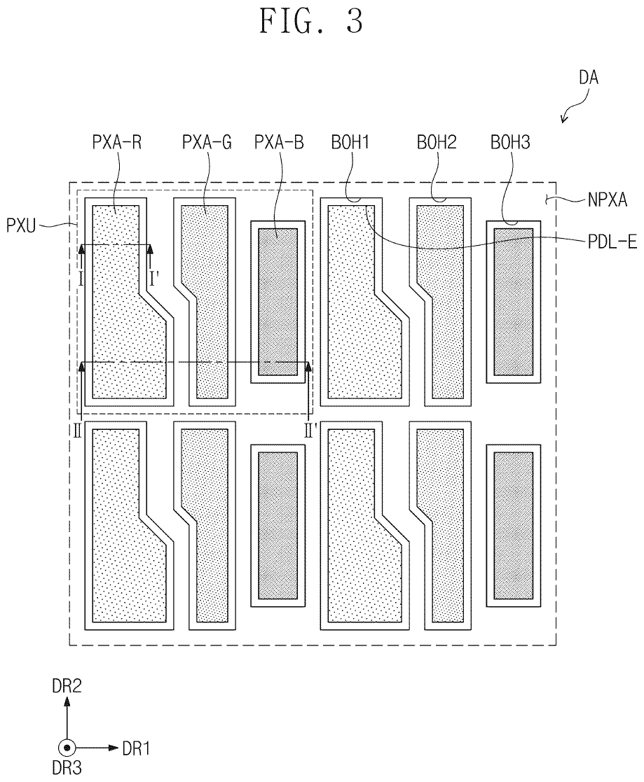

FIG. 2A is a perspective view of a display module according to one or more embodiments of the present disclosure. FIG. 2B is a cross-sectional view of a display module according to one or more embodiments. FIG. 2C is a plan view of a display module according to one or more embodiments.

Referring to FIG. 2A, a display module DM may include a display surface IS, and the display module DM may display an image through the display surface IS. The display surface IS of the display module DM may correspond to a display surface ED-IS of an electronic device ED.

The display surface IS may include a display area DA and a non-display area NDA. A plurality of pixel units PXU may be located in the display area DA. Each of the plurality of pixel units PXU may include a plurality of pixels. The pixels are not located in the non-display area NDA. The non-display area NDA may surround the display area DA (e.g., in plan view). However, one or more embodiments of the present disclosure is not limited thereto, and in one or more embodiments of the present disclosure, the non-display area NDA may be omitted or be located at only one side of the display area DA.

Referring to FIG. 2B, a display module DM according to one or more embodiments may include a display panel DP, and a light control panel OSL located on the display panel DP. The display panel DP may include a base substrate BS, a circuit layer DP-CL, and a display layer DP-ED that are stacked in sequence in a third directional axis DR3 direction. The light control panel OSL may be located on the display layer DP-ED.

In one or more embodiments, the display panel DP may be referred to as a lower panel or a lower display substrate, and the light control panel OSL may be referred to as an upper panel or an upper display substrate.

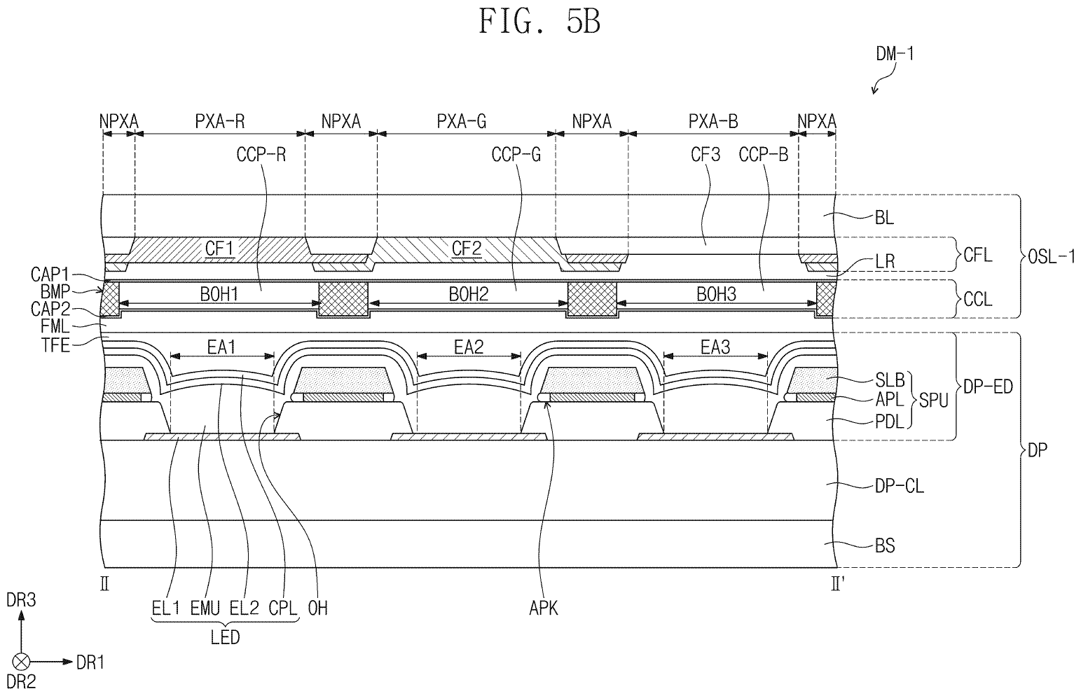

In one or more embodiments, a filling layer FML (see FIG. 5B) may be located between the display panel DP and the light control panel OSL. The display panel DP and the light control panel OSL may be located spaced apart each other with the filling layer FML (see FIG. 5B) therebetween. In this case, the light control panel OSL may be manufactured in a separate process and then provided on the display panel DP.

Alternatively, in the display module DM according to one or more embodiments, the light control panel OSL may be directly located on the display layer DP-ED. In the present disclosure, when a component is referred to as “being directly located/provided” on another component, it means that a third component is not located between the component and the other component. That is, when a component is referred to as “being directly located/provided” on another component, it means that the component and the other component are “in contact with” each other.

In one or more embodiments, the base substrate BS may be a support substrate on which the circuit layer DP-CL and the display layer DP-ED are provided.

The circuit layer DP-CL may include at least one insulating layer and a circuit element. The circuit element includes a signal line, a driving circuit of a pixel, and the like. The circuit layer DP-CL may be formed through a process of forming an insulating layer, a semiconductor layer, and a conductive layer through coating, deposition, or the like, and through a process of patterning the insulating layer, the semiconductor layer, and the conductive layer through photolithography.

The display layer DP-ED includes a display element. The display element may include a light-emitting element that generates light, and that provides the light to the light control panel OSL. The display panel DP including the display layer DP-ED may provide source light to the light control panel OSL located above the display panel DP.

The light control panel OSL may convert a wavelength of the light provided from the display panel DP, or may transmit part of the provided light. The light control panel OSL may include a light control part that converts a wavelength or that transmits light, and structures for increasing photoconversion efficiency of the emitted light.

FIG. 2C illustrates a planar arrangement relationship of signal lines GL1 to GLn and DL1 to DLm and pixels PX11 to PXnm. The signal lines GL1 to GLn and DL1 to DLm may include a plurality of gate lines GL1 to GLn and a plurality of data lines DL1 to DLm.

Each of the pixels PX11 to PXnm is connected to a corresponding gate line of the plurality of gate lines GL1-GLn and a corresponding data line of the plurality of data lines DL1 to DLm. Each of the pixels PX11 to PXnm may include a pixel-driving circuit and a display element. According to the configuration of the pixel-driving circuit of the pixels PX11 to PXnm, more types of signal lines may be provided in the display panel DP.

A gate-driving circuit GDC may be integrated on the display panel DP through an oxide silicon gate (OSG) driver circuit or amorphous silicon gate (ASG) driver circuit process.

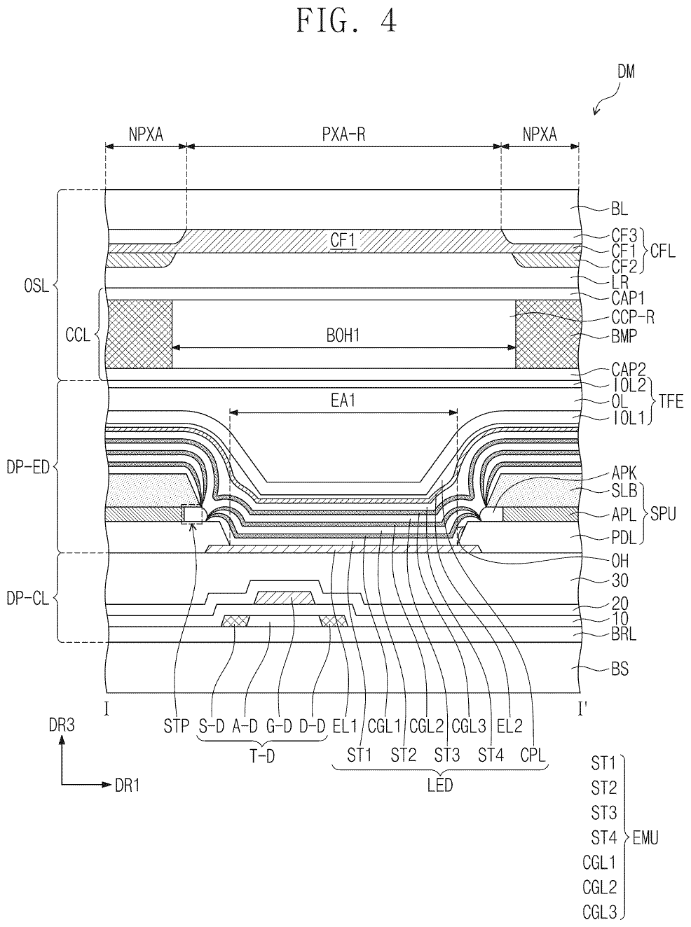

FIG. 3 is an enlarged plan view of a portion of a display module according to one or more embodiments.

FIG. 3 illustrates an arrangement relationship of a plurality of pixel areas located in a display area DA in the display module DM (see FIG. 2A) according to one or more embodiments. In one or more embodiments, three types of pixel areas PXA-R, PXA-G, and PXA-B illustrated in FIG. 3 may be repeatedly located in the entirety of the display area DA (see FIG. 2A). The pixel areas PXA-R, PXA-G, and PXA-B may be referred to as emission areas.

In one or more embodiments, the electronic device ED (see FIG. 1) may include a first pixel area PXA-R, a second pixel area PXA-G, and a third pixel area PXA-B that emit light in different respective wavelength regions. The first to third pixel areas PXA-R, PXA-G, and PXA-B may be divided without overlapping each other when viewed on a plane.

The first pixel area PXA-R may emit light having an emission wavelength of about 610 nm to about 700 nm, the second pixel area PXA-G may emit light having an emission wavelength of about 500 nm to about 590 nm, and the third pixel area PXA-B may emit light having an emission wavelength of about 410 nm to about 480 nm.

In one or more embodiments, the first pixel area PXA-R may be a red pixel area that emits red light, the second pixel area PXA-G may be a green pixel area that emits green light, and the third pixel area PXA-B may be a blue pixel area that emits blue light. However, one or more embodiments is not limited thereto, and in one or more embodiments, in addition to the first to third pixel areas PXA-R, PXA-G, and PXA-B, a pixel area that emits white light may be further included in the display area DA.

In one or more embodiments, one first pixel area PXA-R, one second pixel area PXA-G, and one third pixel area PXA-B may be grouped to constitute one pixel unit PXU. The arrangement of the pixel areas illustrated in FIG. 3 and the like is an example, and unlike the illustrated embodiments, in addition to the first to third pixel areas, a pixel area that emits light in a different wavelength region may be further included in the one pixel unit PXU. Alternatively, the number of at least one of the first to third pixel areas included in the one pixel unit PXU may be two or more.

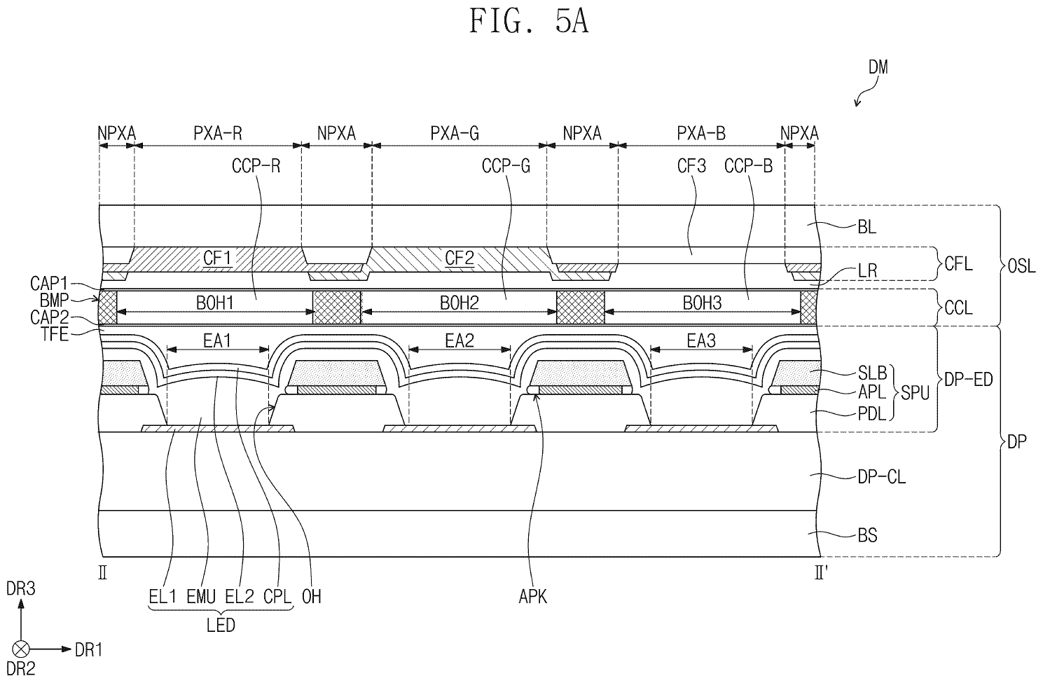

A peripheral area NPXA is located around the first to third pixel areas PXA-R, PXA-G, and PXA-B. The peripheral area NPXA may be referred to as a non-emission area. The peripheral area NPXA may be located in a shape surrounding each of the first pixel area PXA-R, the second pixel area PXA-G, and the third pixel area PXA-B. The peripheral area NPXA may set a boundary of each of the first to third pixel areas PXA-R, PXA-G, and PXA-B, and reduce or prevent color mixture between the first to third pixel areas PXA-R, PXA-G, and PXA-B. In the peripheral area NPXA, a structure for reducing or preventing color mixture between the first to third pixel areas PXA-R, PXA-G, and PXA-B, for example, a pixel-defining layer (e.g., a pixel-defining film) PDL or a division pattern BMP (see FIG. 4), may be located.

In one or more embodiments illustrated in FIG. 3, a portion of the first to third pixel areas PXA-R, PXA-G, and PXA-B may have a rectangular shape. The remaining portion of the first to third pixel areas PXA-R, PXA-G, and PXA-B may have a polygonal shape having a protrusion protruding from a rectangular shape. At least a portion of each of the first to third pixel areas PXA-R, PXA-G, and PXA-B may have a polygonal shape having a short side extending in the first direction DR1 and a long side extending in the second direction DR2. Respective surface areas of the first to third pixel areas PXA-R, PXA-G, and PXA-B may be set according to emissive colors. A surface area of a pixel area that emits light of blue color that is one of primary colors may be the smallest, and a surface area of a pixel area that emits light of red color that is one of the primary colors may be the largest. Alternatively, the surface area of the pixel area, which emits the red light, and a surface area of a pixel area that emits green light may be substantially the same.

FIG. 3 illustrates the first to third pixel areas PXA-R, PXA-G, and PXA-B having a rectangular shape or a polygonal shape, but one or more embodiments of the present disclosure is not limited thereto. A portion of the first to third pixel areas PXA-R, PXA-G, and PXA-B may have a polygonal shape (including a substantially polygonal shape) with a different shape on a plane. In one or more embodiments, each of the first to third pixel areas PXA-R, PXA-G, and PXA-B may have a rectangular shape with rounded corner areas (substantially rectangular shape) or a polygonal shape with rounded corner areas (substantially polygonal shape) on a plane.

In one or more embodiments, a bank well area may be defined in the display area DA. The bank well area may be an area in which a bank well is defined to reduce or prevent the likelihood of a defect due to ink application errors in a process of printing a portion of the plurality of light control parts CCP-R, CCP-G, and CCP-B (see FIG. 5A) included in a light control layer CCL (see FIG. 5A). That is, the bank well area may be an area in which a bank well formed by removing a portion of a division pattern BMP (see FIG. 5A) is defined.

FIG. 4 is a cross-sectional view of a portion of a display module according to one or more embodiments. FIGS. 5A to 5C are each a cross-sectional view of a portion of a display module according to one or more embodiments. FIG. 4 may correspond to a cross-section corresponding to cutting line I-I′ illustrated in FIG. 3, and FIGS. 5A to 5C may each correspond to a cross-section corresponding to cutting line II-II′ illustrated in FIG. 3. FIG. 4 illustrates a cross-section of a display module corresponding to one pixel area, and FIGS. 5A to 5C each illustrate a cross-section of a display module corresponding to three neighboring pixel areas.

Unlike FIG. 4, FIGS. 5A to 5C each schematically illustrate a configuration of a circuit layer DP-CL, an encapsulation layer TFE, and a light-emitting element LED, and the same detailed structure of a display layer illustrated in FIG. 4 may apply to a configuration of a display layer in a plurality of pixel areas in FIGS. 5A to 5C.

Referring to FIGS. 4 to 5C, a display panel DP according to one or more embodiments may include a base substrate BS, the circuit layer DP-CL located on the base substrate BS, and a display layer DP-ED located on the circuit layer DP-CL (as used herein, “located on” may mean “above”). The display layer DP-ED may include a separation structure SPU, the light-emitting element LED including a portion, in which at least a partial area is disconnected by the separation structure SPU, and the encapsulation layer TFE that covers an upper portion of the light-emitting element LED.

The separation structure SPU may include a pixel-defining layer PDL, an auxiliary layer APL located on the pixel-defining layer PDL, and a separator SLB located on the auxiliary layer APL. Respective edges of the pixel-defining layer PDL, the auxiliary layer APL, and the separator SLB, which are stacked in the third direction DR3 that is a thickness direction, may not overlap each other.

A stepped space STP may be defined on the pixel-defining layer PDL to be adjacent to a side of an emission opening portion OH. The stepped space STP may be a portion having an undercut shape defined by the edges of the auxiliary layer APL and the separator SLB.

A portion of functional layers of the light-emitting element LED may be disconnected and located on the basis of the stepped space STP. An air pocket APK may be defined by a space surrounded by a portion of the functional layer of the light-emitting element LED that is disconnected and exposed, a side surface of the auxiliary layer APL, a bottom surface of the separator SLB, and a top surface of the pixel-defining layer PDL that is exposed. Components of the light-emitting element LED may not be located in the air pocket APK. The air pocket APK may be a portion corresponding to an empty space in which an organic layer or an inorganic layer is not located.

The stepped space STP and an arrangement shape of the light-emitting element LED around the stepped space STP will be described later in detail.

In the display panel DP according to one or more embodiments, the base substrate BS may be a member that provides a reference surface on which a component included in the circuit layer DP-CL is located. In one or more embodiments, the base substrate BS may be a glass substrate, a metal substrate, a polymer substrate, or the like. However, one or more embodiments is not limited thereto, and the base substrate BS may include an inorganic layer, a functional layer, or a composite material layer.

The base substrate BS may have a multilayer structure. For example, the base substrate BS may have a three-layer structure including a polymer resin layer, an adhesive layer, and a polymer resin layer. For example, the polymer resin layer may include a polyimide-based resin. The polymer resin layer may include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin. The term “α-based” resin used herein indicates one including a functional group of “α”.

The circuit layer DP-CL may be located on the base substrate BS, and the circuit layer DP-CL may include a transistor T-D as a circuit element. As a driving circuit of the pixel PX (see FIG. 2A) is designed, the configuration of the circuit layer DP-CL may be changed, and in one or more embodiments, the circuit layer DP-CL may include a plurality of types of transistors that perform different functions.

As an example, FIG. 4 illustrates one transistor T-D. In one or more embodiments, the transistor T-D illustrated in FIG. 4 may be a driving transistor electrically connected to the light-emitting element LED. As an example, FIG. 4 illustrates an arrangement relationship of an active A-D, a source S-D, a drain D-D, and a gate G-D that constitute the transistor T-D. The active A-D, the source S-D, and the drain D-D may be areas divided according to a doping concentration or conductivity of a semiconductor pattern.

In one or more embodiments, the semiconductor pattern in the transistor T-D may include a metal oxide. For example, the semiconductor pattern that constitutes the active A-D, the source S-D, and the drain D-D of the transistor T-D may include a metal oxide including at least one of indium, gallium, zinc, tin, or titanium. Although FIG. 4 illustrates only one transistor, the circuit layer DP-CL may include a plurality of transistors, and in at least one of the plurality of transistors, the semiconductor pattern may include a metal oxide.

In addition, in one or more embodiments, the transistor T-D may have a top-gate structure in which the gate G-D is located above the semiconductor pattern.

The circuit layer DP-CL may include a lower buffer layer BRL, a first insulating layer 10, a second insulating layer 20, and a third insulating layer 30 that are located on the base substrate BS. For example, the lower buffer layer BRL, the first insulating layer 10, and the second insulating layer 20 may be inorganic layers, and the third insulating layer 30 may be an organic layer.

The display layer DP-ED may include the light-emitting element LED as a display element. The light-emitting element LED may generate source light. The source light generated and emitted by the light-emitting element LED may be provided to a light control panel OSL, and in a light control layer CCL of the light control panel OSL, at least a portion of the source light may be converted to light having a different wavelength from the source light, or at least a portion of the source light may be transmitted without wavelength conversion.

In one or more embodiments, the source light may include blue light. In one or more embodiments, the source light may be light in which the blue light, and light in a different wavelength region that is different from the blue light, are mixed. In one or more embodiments, the display layer DP-ED may include an organic light-emitting diode as a light-emitting element. The light-emitting element LED may include an organic light-emitting material as a light-emitting material.

The light-emitting element LED includes a first electrode EL1, a second electrode EL2 facing the first electrode EL1, and an emission unit EMU located between the first electrode EL1 and the second electrode EL2. The light-emitting element LED may further include a capping layer CPL located on the second electrode EL2.

In one or more embodiments, the emission unit EMU may include two or more emission structures ST1, ST2, ST3, and ST4 that are separated from each other and stacked in the thickness direction. Each of the emission structures ST1, ST2, ST3, and ST4 may include an emission layer. That is, the light-emitting element LED according to one or more embodiments may be a tandem light-emitting element including a plurality of emission layers stacked in the thickness direction. In addition, the emission unit EMU according to one or more embodiments may include one or more charge generation layers CGL1, CGL2, and CGL3. Each of the charge generation layers CGL1, CGL2, and CGL3 may be located between the stacked emission structures.

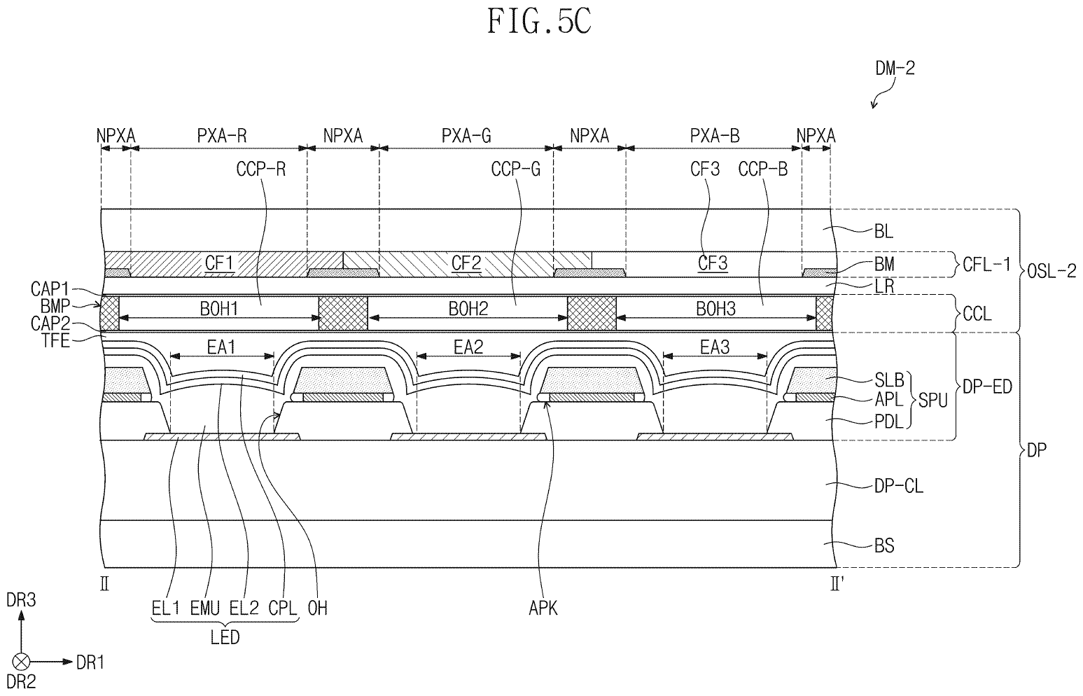

FIG. 6 is a cross-sectional view of a light-emitting element LED according to one or more embodiments. Referring to FIG. 6, the light-emitting element LED according to one or more embodiments may include a first electrode EL1, a second electrode EL2 facing the first electrode EL1, and first to fourth emission structures ST1, ST2, ST3, and ST4 and first to third charge generation layers CGL1, CGL2, and CGL3, which are located between the first electrode EL1 and the second electrode EL2. A structure of the light-emitting element LED illustrated in FIG. 6 is illustrative, and the number of the emission structures that constitute the light-emitting element LED, and the number of the charge generation layers stacked accordingly may be changed. For example, the light-emitting element LED may include two or three emission structures or five or more emission structures.

The stacked structure of the plurality of emission structures ST1, ST2, ST3, and ST4 and the charge generation layers CGL1, CGL2, and CGL3 each located therebetween may be a portion corresponding to the emission unit EMU illustrated in FIGS. 4 to 5C.

Referring to FIG. 6, the first charge generation layer CGL1 may be located between the first emission structure ST1 and the second emission structure ST2, the second charge generation layer CGL2 may be located between the second emission structure ST2 and the third emission structure ST3, and the third charge generation layer CGL3 may be located between the third emission structure ST3 and the fourth emission structure ST4.

The plurality of emission structures ST1, ST2, ST3, and ST4 may include emission layers BEML1, BEML2, BEML3, and GEML, respectively. That is, the light-emitting element LED according to one or more embodiments includes the plurality of emission layers stacked in the thickness direction, and may be referred to as a tandem light-emitting element.

In one or more embodiments, the light-emitting element LED may emit light in a direction from the first electrode EL1 to the second electrode EL2. The first emission structure ST1 may include a first emission layer BEML1, the second emission structure ST2 may include a second emission layer BEML2, the third emission structure ST3 may include a third emission layer BEML3, and the fourth emission structure ST4 may include a fourth emission layer GEML. Some of the emission layers included in the first to fourth emission structures ST1, ST2, ST3, and ST4 may emit light of substantially the same color, and some thereof may emit light of a different color from the remaining emission layers.

In one or more embodiments, the first to third emission layers BEML1, BEML2, and BEML3 of the first to third emission structures ST1, ST2, and ST3 may emit light of substantially the same first color. For example, the light of the first color may be blue light. The light emitted by the first to third emission layers BEML1, BEML2, and BEML3 may have a wavelength range of about 420 nm to about 480 nm.

The fourth emission layer GEML of the fourth emission structure ST4 may emit light of a second color that is different from the light of the first color. For example, the light of the second color may be green light. The light emitted by the fourth emission layer GEML may have a wavelength range of about 520 nm to about 600 nm.

The light-emitting element LED according to one or more embodiments may include at least one blue emission structure that emits blue light, and at least one green emission structure that emits green light, and, in the light-emitting element LED according to one or more embodiments illustrated in FIG. 6, the first to third emission structures ST1, ST2, and ST3 may each be the blue emission structure, and the fourth emission structure ST4 may be the green emission structure. However, arrangement characteristics of the emission structures in the light-emitting element LED are not limited to the illustrated embodiments. Unlike the one or more embodiments corresponding to FIG. 6, the number of each of the blue emission structures and the green emission structure that are included in the light-emitting element LED may be changed, and also, an arrangement position of the blue emission structure and an arrangement position of the green emission structure may be variously combined.

In the case in which at least one of the plurality of emission structures ST1, ST2, ST3, or ST4 is the green emission structure, and at least one of the remainder is the blue emission structure, the number of each of the green emission structure and the blue emission structure, which are included in the light-emitting element LED, the stacking order thereof, and the like, may be changed according to characteristics of source light required by the display panel DP (see FIG. 4).

The light-emitting element LED according to one or more embodiments illustrated in FIG. 6 may be included in a display layer DP-ED of each of display modules DM, DM-1, and DM-2 according to one or more embodiments illustrated in FIGS. 4 to 5C. The display layer DP-ED including the light-emitting element LED according to one or more embodiments may include, as source light, emissive green light and emissive blue light, and the source light may be transferred to a light control layer CCL.

In the light-emitting element LED according to one or more embodiments, the plurality of emission structures ST1, ST2, ST3, and ST4 may include hole transport regions HTR1, HTR2, HTR3, and HTR4 and electron transport regions ETR1, ETR2, ETR3, and ETR4, respectively. The hole transport regions HTR1, HTR2, HTR3, and HTR4 may transport holes provided from the first electrode EL1 or the charge generation layers CGL1, CGL2, and CGL3 to the emission layers. The electron transport regions ETR1, ETR2, ETR3, and ETR4 may transport electrons provided from the second electrode EL2 or the charge generation layers CGL1, CGL2, and CGL3 to the emission layers.

As an example, the light-emitting element LED according to one or more embodiments is illustrated as having a structure in which, based on a direction in which the light is emitted, the hole transport regions HTR1, HTR2, HTR3, and HTR4 are located below the emission layers BEML1, BEML2, BEML3, and GEML included in the plurality of emission structures ST1, ST2, ST3, and ST4, respectively, and the electron transport regions ETR1, ETR2, ETR3, and ETR4 are located above the emission layers BEML1, BEML2, BEML3, and GEML included in the plurality of emission structures ST1, ST2, ST3, and ST4, respectively. That is, the light-emitting element LED according to one or more embodiments may have a forward device structure. However, one or more embodiments of the present disclosure is not limited thereto, and the light-emitting element LED may have an inverted device structure in which, based on the direction in which the light is emitted, the electron transport regions ETR1, ETR2, ETR3, and ETR4 are located below the emission layers BEML1, BEML2, BEML3, and GEML included in the plurality of emission structures ST1, ST2, ST3, and ST4, respectively, and the hole transport regions HTR1, HTR2, HTR3, and HTR4 are located above the emission layers BEML1, BEML2, BEML3, and GEML included in the plurality of emission structures ST1, ST2, ST3, and ST4, respectively.

The hole transport regions HTR1, HTR2, HTR3, and HTR4 may include hole injection layers HIL1, HIL2, HIL3, and HIL4, and hole transport layers HTL1, HTL2, HTL3, and HTL4 located on the hole injection layers HIL1, HIL2, HIL3, and HIL4, respectively. Each of the hole transport layers HTL1, HTL2, HTL3, and HTL4 may be in contact with a bottom surface of the emission layer. However, one or more embodiments of the present disclosure is not limited thereto, and the hole transport regions HTR1, HTR2, HTR3, and HTR4 may further include hole-side additional layers located on the hole transport layers HTL1, HTL2, HTL3, and HTL4, respectively. The hole-side additional layer may include at least one of a hole buffer layer, an emission auxiliary layer, or an electron-blocking layer. The hole buffer layer may be a layer that compensates a resonance distance according to wavelengths of light emitted from the emission layer and increases light emission efficiency. The electron-blocking layer may be a layer that serves to reduce or prevent electrons injected from an electron transport region to a hole transport region. Alternatively, at least one of the hole transport regions HTR1, HTR2, HTR3, or HTR4 may include only one layer, and for example, the hole transport regions HTR1, HTR2, HTR3, and HTR4 may consist of the hole transport layers HTL1, HTL2, HTL3, and HTL4.

The electron transport regions ETR1, ETR2, ETR3, and ETR4 may include an electron transport layer. The electron transport regions ETR1, ETR2, ETR3, and ETR4 may further include an electron injection layer located on the electron transport layer. For example, the fourth electron transport region ETR4 included in the fourth emission structure ST4 may further include a fourth electron injection layer EIL4 located on a fourth electron transport layer ETL4. The electron transport regions ETR1, ETR2, ETR3, and ETR4 may further include an electron-side additional layer located between the electron transport layer and the emission layers. The electron-side additional layer may include at least one of an electron buffer layer or a hole-blocking layer.

In the light-emitting element LED according to one or more embodiments, the first electrode EL1 may be a reflective electrode. For example, the first electrode EL1 may include Ag, Mg, Cu, Al, Pt, Pd, Au, Ni, Nd, Ir, Cr, Li, Ca, LiF/Ca, LiF/Al, Mo, Ti, W, In, Zn, or Sn, which has a high reflectance, or a compound or mixture thereof (e.g., a mixture of Ag and Mg). Alternatively, the first electrode EL1 may have a multilayer structure including a reflective film including the foregoing material, and a transparent conductive film including an indium tin oxide (ITO), an indium zinc oxide (IZO), a zinc oxide (ZnO), an indium tin zinc oxide (ITZO), or the like. For example, the first electrode EL1 may have a two-layer structure of ITO/Ag and a three-layer structure of ITO/Ag/ITO, but is not limited thereto. Also, one or more embodiments is not limited thereto, and the first electrode EL1 may include the foregoing metal material, a combination of two or more metal materials selected from the foregoing metal materials, an oxide of the foregoing metal materials, or the like.

In the light-emitting element LED according to one or more embodiments, the second electrode EL2 may be a semi-transmissive electrode or a transmissive electrode. In a case in which the second electrode EL2 is a transmissive electrode, the second electrode EL2 may include a transparent metal oxide, for example, an indium tin oxide (ITO), an indium zinc oxide (IZO), a zinc oxide (ZnO), an indium tin zinc oxide (ITZO), or the like.

In a case in which the second electrode EL2 is a semi-transmissive electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, In, Zn, Sn, or a compound or mixture thereof (e.g., AgMg, AgYb, or MgAg). Alternatively, the second electrode EL2 may have a multilayer structure including a reflective film or semi-transmissive film including the foregoing material, and a transparent conductive film including an indium tin oxide (ITO), an indium zinc oxide (IZO), a zinc oxide (ZnO), an indium tin zinc oxide (ITZO), or the like. For example, the second electrode EL2 may include the foregoing metal material, a combination of two or more metal materials selected from the foregoing metal materials, an oxide of the foregoing metal materials, or the like.

In the light-emitting element LED according to one or more embodiments, the emission structures ST1, ST2, ST3, and ST4 may include the hole transport regions HTR1, HTR2, HTR3, and HTR4, respectively. The hole transport regions HTR1, HTR2, HTR3, and HTR4 may each include a common hole transport material.

Each of the hole transport regions HTR1, HTR2, HTR3, and HTR4 may be formed using various methods, such as a vacuum deposition method, a spin coating method, a cast method, a Langmuir-Blodgett (LB) method, an inkjet printing method, a laser printing method, or a laser induced thermal imaging method.

Each of the hole transport regions HTR1, HTR2, HTR3, and HTR4 may have a single layer made of a single material, or a single layer made of a plurality of different materials, or a multilayer structure having a plurality of layers made of a plurality of different materials.

Each of the emission layers BEML1, BEML2, BEML3, and GEML may have a single layer made of a single material, or a single layer made of a plurality of different materials, or a multilayer structure having a plurality of layers made of a plurality of different materials. Each of the emission layers BEML1, BEML2, BEML3, and GEML may include a fluorescent material or a phosphorescent material. In the light-emitting element according to one or more embodiments, each of the emission layers BEML1, BEML2, BEML3, and GEML may include a light-emitting material, such as an organic light-emitting material, an organometallic complex, or a quantum dot.

In the light-emitting element LED according to one or more embodiments, each of the emission layers BEML1, BEML2, BEML3, and GEML may include an anthracene derivative, a pyrene derivative, a fluoranthene derivative, a chrysene derivative, a dihydrobenzanthracene derivative, a triphenylene derivative, or the like. However, one or more embodiments is not limited thereto, and the emission layers BEML1, BEML2, BEML3, and GEML may include common light-emitting materials.

The emission structures ST1, ST2, ST3, and ST4 of the light-emitting element LED according to one or more embodiments may include the electron transport regions ETR1, ETR2, ETR3, and ETR4, respectively. Each of the electron transport regions ETR1, ETR2, ETR3, and ETR4 may have a single layer made of a single material, or a single layer made of a plurality of different materials, or a multilayer structure having a plurality of layers made of a plurality of different materials. For example, at least a portion of the electron transport regions ETR1, ETR2, ETR3, and ETR4 may include the electron transport layer ETL4 and the electron injection layer EIL4.

The electron transport regions ETR1, ETR2, ETR3, and ETR4 may each include a common electron transport material. Each of the electron transport regions ETR1, ETR2, ETR3, and ETR4 may be formed using various methods, such as a vacuum deposition method, a spin coating method, a cast method, a LB method, an inkjet printing method, a laser printing method, or a laser induced thermal imaging method.

The capping layer CPL may be further located on the second electrode EL2 of the light-emitting element LED according to one or more embodiments. The capping layer CPL may have a multilayer structure or a single-layer structure. In one or more embodiments, the capping layer CPL may be an organic layer or an inorganic layer. For example, in a case in which the capping layer CPL includes an inorganic material, the inorganic material may include an alkaline metal compound, such as LiF, an alkaline earth metal compound, such as MgF₂, SiON, SiNₓ, SiO_{y}, or the like.

For example, in a case in which the capping layer CPL includes an organic material, the organic material may include α-NPD, NPB, TPD, m-MTDATA, Alq₃, CuPc, N4,N4,N4′,N4′-tetra (biphenyl-4-yl) biphenyl-4,4′-diamine (TPD15), 4,4′,4″-Tris (carbazol sol-9-yl) triphenylamine (TCTA), or the like, or include an epoxy resin, or an acrylate, such as a methacrylate. The capping layer CPL may include an aryl amine-based compound.

The capping layer CPL may have a refractive index of about 1.6 or more. For example, the refractive index of the capping layer CPL with respect to light having a wavelength range of about 550 nm to about 660 nm may be about 1.6 or more.

When a voltage is applied, each of the first to third charge generation layers CGL1, CGL2, and CGL3 may generate charges (electrons and holes) by forming a complex through an oxidation-reduction reaction. Thereafter, each of the first to third charge generation layers CGL1, CGL2, and CGL3 may provide the generated charges to adjacent emission structures among the emission structures ST1, ST2, ST3, and ST4. The first to third charge generation layers CGL1, CGL2, and CGL3 may double efficiency of current generated from the adjacent emission structures ST1, ST2, ST3, and ST4, and may serve to adjust the balance of the charges between the adjacent emission structures ST1, ST2, ST3, and ST4.

Each of the first to third charge generation layers CGL1, CGL2, and CGL3 may include an n-type layer and a p-type layer. The first to third charge generation layers CGL1, CGL2, and CGL3 may have a structure in which the n-type layer and the p-type layer are bonded to each other. However, one or more embodiments of the present disclosure is not limited thereto, and the first to third charge generation layers CGL1, CGL2, and CGL3 may include only one of the n-type layer or the p-type layer. The n-type layer may be a charge generation layer that provides electrons to an adjacent stack. The n-type layer may be a layer in which a base material is doped with an n-dopant. The p-type layer may be a charge generation layer that provides holes to an adjacent stack.

In one or more embodiments, each of the first to third charge generation layers CGL1, CGL2, and CGL3 may have a thickness of about 1 angstrom (Å) to about 150 angstroms (Å). The n-dopant doped in the first to third charge generation layers CGL1, CGL2, and CGL3 may have a concentration of about 0.1% to about 3%, and, for example, about 1% or less. When the concentration is less than about 0.1%, effects of the first to third charge generation layers CGL1, CGL2, and CGL3 that adjust the balance of the charges may hardly occur. When the concentration is more than about 3%, the light efficiency of the light-emitting element LED may be decreased.

Each of the first to third charge generation layers CGL1, CGL2, and CGL3 may include a charge generation compound including an aryl amine-based organic compound, a metal, an oxide, carbide, or fluoride of metal, or a mixture thereof. For example, the aryl amine-based organic compound may include α-NPD, 2-TNATA, TDATA, MTDATA, sprio-TAD, or sprio-NPB. The metal may include cesium (Cs), molybdenum (Mo), vanadium (V), titanium (Ti), tungsten (W), barium (Ba), or lithium (Li). The oxide, carbide, and fluoride of metal may include Re₂O₇, MoO₃, V₂O₅, WO₃, TiO₂, Cs₂CO₃, BaF₂, LiF, or CsF. However, the materials of the first to third charge generation layers CGL1, CGL2, and CGL3 are not limited to the foregoing examples.

Referring to FIGS. 4 to 5C again, the first electrode EL1 of the light-emitting element LED may be directly or indirectly connected to the transistor T-D, and a connecting structure of the first electrode EL1 and the transistor T-D may vary in one or more embodiments. The first electrode EL1 may be an anode or a cathode. The first electrode EL1 may be a pixel electrode. The first electrode EL1 may be a transmissive electrode, a semi-transmissive electrode, or a reflective electrode.

The second electrode EL2 may oppose the first electrode EL1 with the emission unit EMU therebetween. The second electrode EL2 may be a common electrode. The second electrode EL2 may be a cathode or an anode, but one or more embodiments is not limited thereto. For example, in a case in which the first electrode EL1 is an anode, the second electrode EL2 may be a cathode, and in a case in which the first electrode EL1 is a cathode, the second electrode EL2 may be an anode. The second electrode EL2 may be a transmissive electrode, a semi-transmissive electrode, or a reflective electrode.

The first electrode EL1 may be divided and located to correspond to each of pixel areas PXA-R, PXA-G, and PXA-B. The second electrode EL2 may be provided as a common layer to the entirety of the pixel areas PXA-R, PXA-G, and PXA-B. In addition, in one or more embodiments, the capping layer CPL may be provided, on the second electrode EL2, as a common layer to the entirety of the pixel areas PXA-R, PXA-G, and PXA-B.

In the display panel DP according to one or more embodiments, the emission unit EMU may be provided as a common layer to the entirety of the pixel areas PXA-R, PXA-G, and PXA-B. However, one or more embodiments is not limited thereto, and a portion of functional layers of the light-emitting element included in the emission unit EMU may be divided and located to correspond to each of the pixel areas PXA-R, PXA-G, and PXA-B. In one or more embodiments, charge generation layers CGL1, CGL2, and CGL3 of the light-emitting element LED may each be provided as a common layer to the entirety of the pixel areas PXA-R, PXA-G, and PXA-B, and at least one of the charge generation layers CGL1, CGL2, or CGL3 may have a structure disconnected at a portion corresponding to the separation structure SPU that divides the pixel areas PXA-R, PXA-G, and PXA-B.

Referring to FIGS. 4 and 5A, the display layer DP-ED may include the encapsulation layer TFE that protects the light-emitting element LED. The encapsulation layer TFE may include an organic material or an inorganic material. The encapsulation layer TFE may have a multilayer structure in which an inorganic layer/an organic layer are repeated.

Referring to FIG. 4, in one or more embodiments, the encapsulation layer TFE may include a first inorganic layer IOL1, an organic layer OL, and a second inorganic layer IOL2 that are stacked in sequence. However, the layers that constitute the encapsulation layer TFE are not limited thereto. The encapsulation layer TFE may be directly provided on the light-emitting element LED in a continuous process.

The first and second inorganic layers IOL1 and IOL2 may protect the light-emitting element LED from moisture and oxygen, and the organic layer OL may protect the light-emitting element LED from foreign matter, such as dust particles. For example, the organic layer OL may reduce or prevent the likelihood of a dent defect of the light-emitting element LED caused by foreign matter introduced during a manufacture process. In one or more embodiments, the display panel DP may further include a refractive index control layer that is located on the encapsulation layer TFE and to improve luminance efficiency.

The inorganic layers IOL1 and IOL2 may each include at least one of silicon nitride, silicon oxynitride, silicon oxide, titanium oxide, or aluminum oxide. The organic layer OL may include an acrylic organic material. However, the types of the materials that constitute the inorganic layers IOL1 and IOL2 and the organic layer OL are not limited thereto.

Referring to FIGS. 4 to 5C, in the display modules DM, DM-1, and DM-2 according to one or more embodiments, light control panels OSL, OSL-1 and OSL-2 may each be located on the encapsulation layer TFE.

Referring to FIGS. 4 and 5A, in the display module DM according to one or more embodiments, the light control panel OSL may include a light control layer CCL including a quantum dot. In one or more embodiments, the light control layer CCL may be located on the encapsulation layer TFE. The light control panel OSL may further include a color filter layer CFL located on the light control layer CCL. The light control panel OSL may further include a base layer BL.

The light control layer CCL may include a division pattern BMP and a plurality of light control parts CCP-R, CCP-G, and CCP-B. The light control layer CCL may further include at least one of a first barrier layer CAP1 or a second barrier layer CAP2.

The division pattern BMP may be a component that separates the plurality of light control parts CCP-R, CCP-G, and CCP-B from each other. The division pattern BMP may include a base resin and an additive. The base resin may include various resin compositions that may be generally referred to as binders. The additive may include a coupling agent and/or a photoinitiator. The additive may further include a dispersing agent.

The division pattern BMP may include a black component for blocking light. The division pattern BMP may include a black dye or a black pigment, each of that is mixed in the base resin. In one or more embodiments, the black component may include a carbon black, a metal, such as chrome, or an oxide thereof.

Division opening portions BOH1, BOH2, and BOH3 each corresponding to the emission opening portion OH may be defined in the division pattern BMP. On a plane, each of the division opening portions BOH1, BOH2, and BOH3 may overlap the emission opening portion OH, and may have a larger surface area than the emission opening portion OH. That is, the division opening portions BOH1, BOH2, and BOH3 may have larger surface areas than emission areas EA1, EA2, and EA3 defined by the emission opening portions OH, respectively. The light control parts CCP-R, CCP-G, and CCP-B may be respectively located inside the division opening portions BOH1, BOH2, and BOH3.

In one or more embodiments, the light control layer CCL may include a first light control part CCP-R corresponding to a first pixel area PXA-R, a second light control part CCP-G corresponding to a second pixel area PXA-G, and a third light control part CCP-B corresponding to a third pixel area PXA-B. The first light control part CCP-R may be a red light control part that emits red light. The second light control part CCP-G may be a green light control part that emits green light. The third light control part CCP-B may be a blue light control part that emits blue light. Alternatively, the third light control part CCP-B may be a transmission light control part that transmits and emits the source light. At least one of the first to third light control parts CCP-R, CCP-G, and CCP-B of the light control layer CCL may include a quantum dot that converts optical properties of the source light.

The first light control part CCP-R may include a first quantum dot that converts the source light into light having a different wavelength. The second light control part CCP-G may include a second quantum dot that converts the source light into light having a different wavelength. In one or more embodiments, the first quantum dot may convert the source light into the red light, and the second quantum dot may convert the source light into the green light. In one or more embodiments, the first quantum dot may be a red quantum dot, and the second quantum dot may be a green quantum dot.

In the present disclosure, the quantum dot refers to a crystal of a semiconductor compound. The quantum dot may emit light having various emission wavelengths according to the size of the crystal. The quantum dot may emit light having various emission wavelengths by adjusting a ratio of elements in the semiconductor compound.

A diameter of the quantum dot may be, for example, about 1 nm to about 10 nm. The quantum dot may be synthesized through a wet chemical process, an organic metal chemical vapor deposition process, a molecular beam epitaxy process, or a similar process.

Among the quantum dot manufacturing processes, the wet chemical process is a method of mixing an organic solvent and a precursor material and then growing quantum dot particle crystals. When the quantum dot particle crystals grow, the organic solvent may naturally serve as a dispersant coordinated on surfaces of the quantum dot crystals, and may control the growth of the particle crystals. Thus, in the wet chemical process, the growth of the quantum dot particles may be controlled through a process performed more suitably and at lower costs than a vapor deposition process, such as metal organic chemical vapor deposition or molecular beam epitaxy.

A core of the quantum dot may be selected from a Group II-VI compound, a Group III-V compound, a Group III-VI compound, a Group I-III-VI compound, a Group IV-VI compound, a Group IV element, a Group IV compound, and/or a combination thereof.

The Group II-VI compound may be selected from the group comprising a binary compound selected from the group comprising CdSe, CdTe, CdS, ZnS, ZnSe, ZnTe, ZnO, HgS, HgSe, HgTe, MgSe, MgS, and/or a mixture thereof, a ternary compound selected from the group comprising CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or a mixture thereof, and a quaternary compound selected from the group comprising HgZnTeS, CdZnSeS, CdZnSeTe, CdZnSTe, CdHgSeS, CdHgSeTe, CdHgSTe, HgZnSeS, HgZnSeTe, HgZnSTe, and/or a mixture thereof. Meanwhile, a Group II-VI semiconductor compound may further include a Group I metal and/or a Group IV element. The Group I-II-VI compound may be selected from CuSnS or CuZnS, and the Group II-IV-VI compound may be selected from ZnSnS and the like. The Group I-II-IV-VI compound may be selected from a quaternary compound selected from the group comprising Cu₂ZnSnS₂, Cu₂ZnSnS₄, Cu₂ZnSnSe₄, Ag₂ZnSnS₂, and/or a mixture thereof.

The Group III-VI compound may include a binary compound, such as In₂S₃ or In₂Se₃, a ternary compound, such as InGaS₃ or InGaSe₃, or any combination thereof.

The Group I-III-VI compound may be selected from a ternary compound selected from the group comprising AgInS, AgInS₂, CuInS, CuInS₂, AgGaS₂, CuGaS₂ CuGaO₂, AgGaO₂, AgAlO₂, and/or a mixture thereof, or a quaternary compound, such as AgInGaS₂ or CuInGaS₂.

The Group III-V compound may be selected from the group comprising a binary compound selected from the group comprising GaN, GaP, GaAs, GaSb, AlN, AlP, AlAs, AlSb, InN, InP, InAs, InSb, and/or a mixture thereof, a ternary compound selected from the group comprising GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and/or a mixture thereof, and a quaternary compound selected from the group comprising GaAlNP, GaAlNAs, GaAINSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or a mixture thereof. Meanwhile, the Group III-V compound may further include a Group II metal. For example, the Group III-II-V compound may be selected from InZnP and the like.

The Group IV-VI compound may be selected from the group comprising a binary compound selected from the group comprising SnS, SnSe, SnTe, PbS, PbSe, PbTe, and/or a mixture thereof, a ternary compound selected from the group comprising SnSeS, SnSeTe, SnSTe, PbSeS, PbSeTe, PbSTe, SnPbS, SnPbSe, SnPbTe, and/or a mixture thereof, and a quaternary compound selected from the group comprising SnPbSSe, SnPbSeTe, SnPbSTe, and/or a mixture thereof.

Examples of the Group II-IV-V compound may include a ternary compound selected from the group comprising ZnSnP, ZnSnP₂, ZnSnAs₂, ZnGeP₂, ZnGeAs₂, CdSnP₂, and CdGeP₂, and/or a mixture thereof.

The Group IV element may be selected from the group comprising Si, Ge, and/or a mixture thereof. The Group IV compound may be a binary compound selected from the group comprising SiC, SiGe, and/or a mixture thereof.

Each of elements included in a multi-element compound, such as a binary compound, a ternary compound and a quaternary compound, may be present in a particle at a uniform concentration or non-uniform concentration. That is, the representation of a chemical formula representing a quantum dot indicates types of elements included in a quantum dot compound, and ratios of the elements in the compound may be different.

Here, the binary compound, the ternary compound, or the quaternary compound may be present at a uniform concentration in a particle, or may be present in the same particle while being divided in partially different concentration distributions. In addition, the quantum dot may have a core-shell structure in which one quantum dot surrounds another quantum dot. In the core-shell structure, the quantum dot may have a concentration gradient in which the concentration of elements present in the shell gradually decreases toward the core.

In some embodiments, the quantum dot may have the aforementioned core-shell structure including a core having a nanocrystal and a shell surrounding the core. The shell of the quantum dot may serve as a protective layer for reducing or preventing chemical modification of the core to maintain semiconductor characteristics, and/or serve as a charging layer for imparting electrophoretic characteristics to the quantum dot. The shell may have a single-layer structure or a multilayer structure. Examples of the shell of the quantum dot may include a metal or nonmetal oxide, a semiconductor compound, a combination thereof, or the like.

For example, the metal or nonmetal oxide may include a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound, such as MgAl₂O₄, CoFe₂O₄, NiFe₂O₄, or CoMn₂O₄, but one or more embodiments of the present disclosure is not limited thereto.

In addition, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, but one or more embodiments of the present disclosure is not limited thereto.

For example, in a case in which the quantum dot of the Group III-VI compound has a core-shell structure, the core may include InP or InZnP, and the shell may include ZnSeS or have a dual shell structure of ZnSe/ZnS. However, one or more embodiments is not limited thereto, and the quantum dot may have a combination of a core and a shell, selected from the aforementioned semiconductor compounds.

The quantum dot may have a full width of half maximum (FWHM) of an emission wavelength spectrum of about 45 nm or less, for example about 40 nm or less or even 30 nm or less, and, in this range, color purity or color reproducibility may be improved. In addition, light emitted through such quantum dots is emitted in all directions, thereby improving a viewing angle of light.

The form of the quantum dot is a form generally used in the relevant field, and is not particularly limited. For example, spherical, pyramidal, multi-armed, or cubic nanoparticles, or nanoparticles in the form of nanotubes, nanowires, nanofibers, or nanoplate, or the like, may be used.

In the quantum dot, an energy band gap may be adjusted by adjusting the size of the quantum dot or adjusting the ratio of elements in a quantum dot compound, and thus light in various wavelength bands may be obtained in the quantum dot emission layer. Thus, the quantum dots (having different sizes or having different ratios of elements in a quantum dot compound) as described above may be used to achieve a light-emitting element that emits light having several wavelengths. For example, the size of the quantum dot or the ratio of elements in the quantum dot compound may be selectively adjusted to emit red, green and/or blue light. The quantum dots may be configured to emit white light by combining light of various colors.

In one or more embodiments, as the particle size of the quantum dot is decreased, the quantum dot may emit light in a shorter-wavelength range. For example, in quantum dots having the same core, a particle size of the quantum dot that emits green light may be less than a particle size of the quantum dot that emits red light. In addition, in the quantum dots having the same core, a particle size of the quantum dot that emits blue light may be less than the particle size of the quantum dot that emits the green light. However, one or more embodiments is not limited thereto, and, even in the quantum dots having the same core, the particle sizes thereof may be adjusted according to a material constituting the shell, a shell thickness, and the like.

Meanwhile, in a case in which quantum dots have various emissive colors, such as blue, red, and green, the quantum dots having different emissive colors may be different from each other in terms of the core materials.

The first light control part CCP-R may correspond to the first pixel area (red emission area) PXA-R (see FIG. 5A), the second light control part CCP-G may correspond to the second pixel area (green emission area) PXA-G (see FIG. 5A), and the third light control part CCP-B may correspond to the third pixel area (blue emission area) PXA-B (see FIG. 5A).

In one or more embodiments, the first light control part CCP-R may include red quantum dots, and the second light control part CCP-G may include green quantum dots. The first light control part CCP-R, the second light control part CCP-G, and the third light control part CCP-B may each include a base resin. The first light control part CCP-R, the second light control part CCP-G, and the third light control part CCP-B may each further include a scatterer.

In one or more embodiments, the third light control part CCP-B may not include a quantum dot. However, one or more embodiments is not limited thereto, and the third light control part CCP-B may further include a quantum dot in which light undergoes wavelength conversion to light in different wavelength regions from that of the first and second light control parts.

In one or more embodiments, the scatterer may uniformly scatter and emit the light incident on the light control parts CCP-R, CCP-G, and CCP-B. The scatterer may scatter and emit the source light, or scatter and emit light wavelength-converted from the source light.

The scatterer may have a spherical shape having a diameter between tens of nanometers and hundreds of nanometers. For example, in one or more embodiments, the diameter of the scatterer may be about 50 nm to about 300 nm. For example, in one or more embodiments, the diameter of the scatterer may be about 200 nm.

The scatterer may include an inorganic particle. For example, the scatterer may include TiO₂, BaTiO₃, ZnO, ZnS, Al₂O₃, SiO₂, hollow silica, or the like.

The base resin is a medium in which the quantum dots and the scatterer are dispersed, and may include various resin compositions that may be generally referred to as binders. For example, the base resin may be an acrylate-based resin part, a urethane-based resin part, a silicon-based resin part, an epoxy-based resin part, or the like. The base resin included in the first to third light control parts CCP-R, CCP-G, and CCP-B may be the same, or a base resin part in at least one light control part may be different from base resin parts in the other light control parts.

In one or more embodiments, the light control layer CCL may include the barrier layers CAP1 and CAP2. The barrier layers CAP1 and CAP2 may serve to reduce or prevent permeation of moisture and/or oxygen (hereinafter referred to as “moisture/oxygen”) and adjust a refractive index to improve optical characteristics of the light control layer CCL. The barrier layers CAP1 and CAP2 may be located above or below the light control parts CCP-R, CCP-G, and CCP-B. The barrier layers CAP1 and CAP2 may be located on one surface of an upper side or one surface of a lower side of the light control parts CCP-R, CCP-G, and CCP-B, thereby reducing or preventing exposure of the light control parts CCP-R, CCP-G, and CCP-B to moisture/oxygen. For example, the barrier layers CAP1 and CAP2 may reduce or prevent exposure of the quantum dots included in the light control parts CCP-R, CCP-G, and CCP-B to moisture/oxygen. The barrier layers CAP1 and CAP2 may also protect the light control parts CCP-R, CCP-G, and CCP-B from an external impact.

In one or more embodiments, the first barrier layer CAP1 may be located spaced apart from the display layer DP-ED with the light control parts CCP-R, CCP-G, and CCP-B therebetween. That is, the first barrier layer CAP1 may be located on respective top surfaces of the light control parts CCP-R, CCP-G, and CCP-B. In one or more embodiments, the light control panel OSL may further include the second barrier layer CAP2 located between the light control parts CCP-R, CCP-G, and CCP-B and the display layer DP-ED. In one or more embodiments, the first barrier layer CAP1 may cover the top surfaces of the light control parts CCP-R, CCP-G, and CCP-B, and the second barrier layer CAP2 may cover respective bottom surfaces of the light control parts CCP-R, CCP-G, and CCP-B, which are adjacent to the display layer DP-ED. Meanwhile, in the present disclosure, the term “top surface” may be a surface placed on an upper side on the basis of the third direction DR3, and the term “bottom surface” may be a surface placed on a lower side on the basis of the third direction DR3.

Also, each of the first barrier layer CAP1 and the second barrier layer CAP2 may cover one surface of the division pattern BMP in addition to the light control parts CCP-R, CCP-G, and CCP-B.

The first barrier layer CAP1 and the second barrier layer CAP2 may each include an inorganic material. In one or more embodiments, the first barrier layer CAP1 includes a silicon oxynitride (SiON). Each of the first barrier layer CAP1 and the second barrier layer CAP2 may include a silicon oxynitride. However, one or more embodiments of the present disclosure is not limited thereto. For example, the first barrier layer CAP1 may include a silicon oxynitride, and the second barrier layer CAP2 may include a silicon oxide (SiOₓ).

The light control panel OSL may further include the color filter layer CFL located on the light control layer CCL. The color filter layer CFL includes one or more color filters CF1, CF2, and CF3. The color filter transmits light in a corresponding wavelength range, and blocks light in a wavelength range other than the corresponding wavelength range. In one or more embodiments, a first color filter CF1 may be a red filter that transmits red light, a second color filter CF2 may be a green filter that transmits green light, and a third color filter CF3 may be a blue filter that transmits blue light.

Each of the color filters CF1, CF2, and CF3 includes a polymer photosensitive resin and a coloring agent. The coloring agent may include a pigment or a dye. The first color filter CF1 may include a red pigment or a red dye, the second color filter CF2 may include a green pigment or a green dye, and the third color filter CF3 may include a blue pigment or a blue dye. In one or more embodiments, the third color filter CF3 may not include a pigment or a dye.

The first to third color filters CF1, CF2, and CF3 may correspond to the first pixel area PXA-R, the second pixel area PXA-G, and the third pixel area PXA-B, respectively. In addition, the first to third color filters CF1, CF2, and CF3 may overlap the first to third light control parts CCP-R, CCP-G, and CCP-B, respectively.

In the color filter layer CFL, the plurality of color filters CF1, CF2, and CF3 that transmit different light may overlap each other when corresponding to a peripheral area NPXA. When corresponding to the peripheral area NPXA, the plurality of color filters CF1, CF2, and CF3 may overlap each other in the third direction DR3 that is a thickness direction, thereby defining a boundary between adjacent pixel areas of the pixel areas PXA-R, PXA-G, and PXA-B. In one or more embodiments, the color filter layer CFL may include a light-blocking part as a component that defines a boundary between adjacent color filters among the color filters CF1, CF2, and CF3. In one or more embodiments, the light-blocking part may be provided as a blue filter or include an organic light-blocking material or an inorganic light-blocking material each including a black pigment or a black dye.

The light control panel OSL may further include a low refractive layer LR located between the light control layer CCL and the color filter layer CFL. The low refractive layer LR may be directly located on the first barrier layer CAP1, and the color filter layer CFL may be directly located on the low refractive layer LR.

The low refractive layer LR may be located above the light control layer CCL, and may reduce or prevent exposure of the light control parts CCP-R, CCP-G, and CCP-B to moisture/oxygen. In addition, the low refractive layer LR may function as an optical functional layer that is located between the light control parts CCP-R, CCP-G, and CCP-B and the color filters CF1, CF2, and CF3 and increases light extraction efficiency or reduces or prevents incidence of reflected light on the light control layer CCL. The low refractive layer LR may be a layer having a lower refractive index than to an adjacent layer.

The low refractive layer LR may include at least one inorganic layer. For example, the low refractive layer LR may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, and a silicon oxynitride, a metal thin film having light transmittance, and the like. However, one or more embodiments is not limited thereto, and the low refractive layer LR may include an organic film. The low refractive layer LR may have, for example, a structure in which a plurality of hollow particles are dispersed in an organic polymeric resin. The low refractive layer LR may include a single layer or a plurality of layers.

In the light control panel OSL according to one or more embodiments, the base layer BL may be a member that provides a reference surface on which the color filter layer CFL, the light control layer CCL, and the like are located. The base layer BL may be a glass substrate, a metal substrate, a plastic substrate, or the like. However, one or more embodiments is not limited thereto, and the base layer BL may be an inorganic layer, an organic layer, or a composite material layer. Alternatively, unlike the illustrated embodiments, the base layer BL may be omitted in one or more embodiments.

FIGS. 5B and 5C are each a cross-sectional view illustrating a portion of a display module according to one or more embodiments. The display modules according to one or more embodiments illustrated in FIGS. 5B and 5C are partially different in terms of the configuration of a light control panel from the display module according to one or more embodiments described with reference to FIGS. 4 and 5A. Hereinafter, the display modules according to one or more embodiments will be described with reference to FIGS. 5B and 5C by avoiding the contents in common with the contents described with reference to FIGS. 4 and 5A, and mainly in terms of the differences.

Referring to FIG. 5B, the display module DM-1 according to one or more embodiments may include a display panel DP including a base substrate BS, a circuit layer DP-CL located on the base substrate BS, and a display layer DP-ED located on the circuit layer DP-CL, and a light control panel OSL-1 located on the display panel DP. The light control panel OSL-1 may include a light control layer CCL, a low refractive layer LR, a color filter layer CFL, and a base layer BL. The display module DM-1 according to one or more embodiments may further include a filling layer FML located between the display panel DP and the light control panel OSL-1.

The display module DM-1 in FIG. 5B may be provided by manufacturing the display panel DP, in which the circuit layer DP-CL and the display layer DP-ED are located on a top surface of the base substrate BS as a base surface, manufacturing the light control panel OSL-1, in which the color filter layer CFL and the light control layer CCL are located on one surface of the base layer BL as a base surface, and then coupling the display panel DP and the light control panel OSL-1 to each other with the filling layer FML therebetween.

In one or more embodiments, the filling layer FML may fill a space between the display panel DP and the light control panel OSL-1. The filling layer FML may be directly located on an encapsulation layer TFE, and a second barrier layer CAP2 may be directly located on the filling layer FML.

In one or more embodiments, the filling layer FML may perform an impact absorbing function or the like, and may increase the strength of the display module DM-1. The filling layer FML may be made from a filling resin including a polymer resin. For example, the filling layer FML may be made from a filling layer resin including an acryl-based resin, an epoxy-based resin, or the like.

In the display module DM-1 according to one or more embodiments, a stepped portion may be generated between a bottom surface of a division pattern BMP and a bottom surface of each of light control parts CCP-R, CCP-G, and CCP-B. The second barrier layer CAP2 may be located while following the stepped portion between the division pattern BMP and each of the light control parts CCP-R, CCP-G, and CCP-B. In the second barrier layer CAP2, the filling layer FML may be directly located on a lower side of the second barrier layer CAP2 and cover the stepped portion of the light control layer CCL.

Referring to FIG. 5C, the display module DM-2 according to one or more embodiments may include a display panel DP including a base substrate BS, a circuit layer DP-CL located on the base substrate BS, and a display layer DP-ED located on the circuit layer DP-CL, and a light control panel OSL-2 located on the display panel DP. In the display module DM-2 according to one or more embodiments, the light control panel OSL-2 may include a light control layer CCL, a low refractive layer LR, a color filter layer CFL-1, and a base layer BL that are stacked in sequence on an encapsulation layer TFE.

The light control layer CCL may include division patterns BMP and light control parts CCP-R, CCP-G, and CCP-B, each of that is located between the division patterns BMP. The light control layer CCL may include a first barrier layer CAP1 and a second barrier layer CAP2 that are located, respectively, on (e.g., contacting) a top surface and a bottom surface of each of the light control parts CCP-R, CCP-G, and CCP-B.

The light control layer CCL may be located on the display layer DP-ED. The low refractive layer LR may be located on the light control layer CCL. The color filter layer CFL-1 may include a plurality of color filters CF1, CF2, and CF3 and a light-blocking part BM.

Compared to the display module DM-1 illustrated in FIG. 5B, the display module DM-2 according to one or more embodiments illustrated in FIG. 5C corresponds to one or more embodiments in which the light control layer CCL, the low refractive layer LR, and the color filter layer CFL-1 are located on a top surface of the encapsulation layer TFE as a base surface. That is, the light control layer CCL may be formed on the encapsulation layer TFE through a continuous process, and the low refractive layer LR and the color filters CF1, CF2, and CF3 of the color filter layer CFL-1 may be formed in sequence on the light control layer CCL through a continuous process.

In one or more embodiments illustrated in FIG. 5C, the color filter layer CFL-1 may have a different shape from the color filter layer CFL according to one or more embodiments illustrated in each of FIGS. 5A and 5B.

In the color filter layer CFL-1 according to one or more embodiments, the light-blocking part BM may be a black matrix. The light-blocking part BM may include an organic light-blocking material or an inorganic light-blocking material each including a black pigment or a black dye. The light-blocking part BM may reduce or prevent light leakage, and may define a boundary between adjacent color filters among the color filters CF1, CF2, and CF3.

In one or more embodiments illustrated in FIGS. 4 to 5C, a pixel-defining layer PDL included in the display panel DP may be an organic layer. An emission opening portion OH is defined in the pixel-defining layer PDL. The emission opening portion OH of the pixel-defining layer PDL exposes at least a portion of a first electrode EL1. The emission areas EA1, EA2, and EA3 may be defined by the emission opening portion OH.

The pixel-defining layer PDL may be made of a polymer resin. For example, the pixel-defining layer PDL may include a polyacrylate-based resin or a polyimide-based resin. The pixel-defining layer PDL may further include an inorganic material in addition to a polymer resin. The pixel-defining layer PDL may include a light-absorbing material, or include a black pigment or a black dye. The pixel-defining layer PDL including the black pigment or the black dye may constitute a black pixel-defining layer. When forming the pixel-defining layer PDL, a carbon black or the like may be used as the black pigment or the black dye, but one or more embodiments is not limited thereto.

The pixel-defining layer PDL may be made of an inorganic material. For example, the pixel-defining layer PDL may be made of an inorganic material, such as silicon nitride (SiNₓ), silicon oxide (SiOₓ), or silicon oxynitride (SiOₓN_{y}).

The display layer DP-ED may include a first emission area EA1, a second emission area EA2, and a third emission area EA3. The first emission area EA1, the second emission area EA2, and the third emission area EA3 may be areas divided by the pixel-defining layer PDL. The first emission area EA1, the second emission area EA2, and the third emission area EA3 may correspond to a first pixel area PXA-R, a second pixel area PXA-G, and a third pixel area PXA-B, respectively. In one or more embodiments, the pixel areas PXA-R, PXA-G, and PXA-B may be areas divided by the color filters CF1, CF2, and CF3.

The first pixel area PXA-R may be an area corresponding to the first emission area EA1 and a first light control part CCP-R, the second pixel area PXA-G may be an area corresponding to the second emission area EA2 and a second light control part CCP-G, and the third pixel area PXA-B may be an area corresponding to the third emission area EA3 and a third light control part CCP-B. An electronic device according to one or more embodiments, the first pixel area PXA-R, the second pixel area PXA-G, and the third pixel area PXA-B, which respectively emit light in different wavelength regions, may be arranged in sequence in the first direction DR1.

In the present disclosure, when two components “correspond to” each other, it may mean that the two components overlap each other when viewed in the thickness direction of the electronic device ED, and is not limited to the meaning that the two components have the same surface area.

An auxiliary layer APL may be located on the pixel-defining layer PDL. The auxiliary layer APL may be directly located between the pixel-defining layer PDL and a separator SLB. The auxiliary layer APL may be a sacrificial layer used for patterning the separator SLB or the like above the auxiliary layer APL.

The auxiliary layer APL may be a layer including a transparent metal oxide. The auxiliary layer APL may be a layer including an amorphous transparent metal oxide.

In one or more embodiments, the transparent metal oxide included in the auxiliary layer APL may be crystallized at a temperature of about 260° C. or more. As the auxiliary layer APL includes a metal oxide material crystallized at the temperature of about 260° C. or more, after a curing process for the separator SLB above the auxiliary layer APL, the auxiliary layer APL may have superior selectivity, and may be thus suitably etched.

The auxiliary layer APL may include an indium zinc oxide (IZO) or an indium gallium zinc oxide (IGZO). In one or more embodiments, the auxiliary layer APL may be made of an indium zinc oxide. In a case in which the auxiliary layer APL is made of an indium zinc oxide, a weight ratio of indium to zinc may be about 9:1 to about 1:1. For example, the weight ratio of indium to zinc may be about 9:1, about 4:1, about 7:3, about 3:2, or about 1:1.

In one or more embodiments, in the case in which the auxiliary layer APL is made of an indium zinc oxide, a weight of indium may be greater than a weight of zinc. Accordingly, the auxiliary layer APL may exhibit the characteristic of being crystallized at the temperature of about 260° C. or more.

In one or more embodiments, the separator SLB may be located on the auxiliary layer APL, and an edge of the separator SLB may protrude further toward a side of the emission opening portion OH than an edge of the auxiliary layer APL. The separator SLB may be an organic film including a black component.

The separator SLB may include a black dye or a black pigment, each of that is mixed in a base resin. In one or more embodiments, the black component may include a carbon black, a metal, such as chrome, or an oxide thereof.

The separator SLB may be located on the pixel-defining layer PDL while not overlapping the emission areas EA1, EA2, and EA3. The separator SLB may be located between emission areas neighboring each other in the first direction among the emission areas EA1, EA2, and EA3 so that the separators SLB are spaced apart from each other. In addition, the separators SLB may each correspond to a space between pixel areas adjacent to each other in the first direction DR1 among the pixel areas PXA-R, PXA-G, and PXA-B.

As the separator SLB includes the black component, the separator SLB may reduce or prevent transfer of light generated and emitted from each of the emission areas EA1, EA2, and EA3 to neighboring pixel areas, not to a corresponding pixel area. The separator SLB may absorb the light that is generated from each of the emission areas EA1, EA2, and EA3 and that is emitted to a side surface.

The display panel according to one or more embodiments may include the separator SLB including the black component, hereby reducing reflection due to external light and decreasing color mixture between adjacent pixel areas to exhibit the excellent color matching ratio and color reproducibility.

In one or more embodiments, the separator SLB may include the black component, and may define a space having an undercut shape on the pixel-defining layer PDL, thereby functioning as a separation structure of the emission areas and as a light-blocking structure that blocks light incident in a lateral direction.

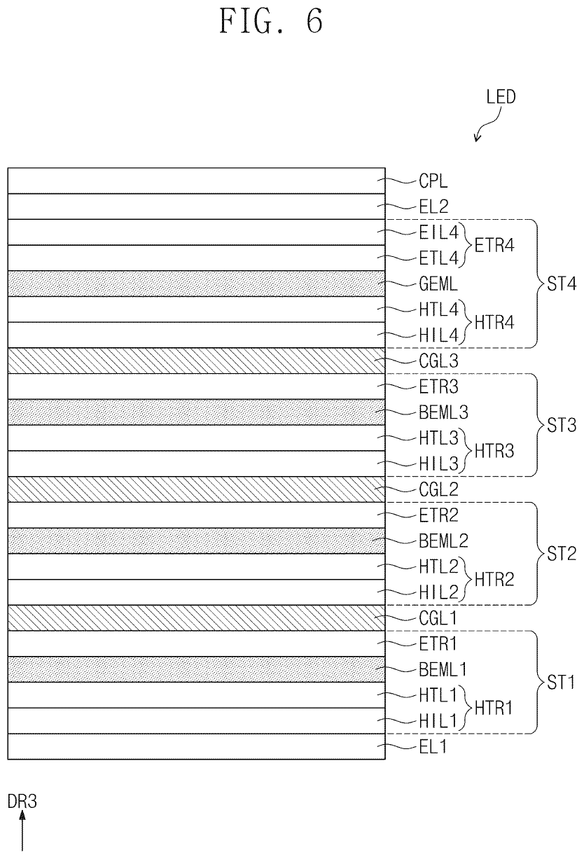

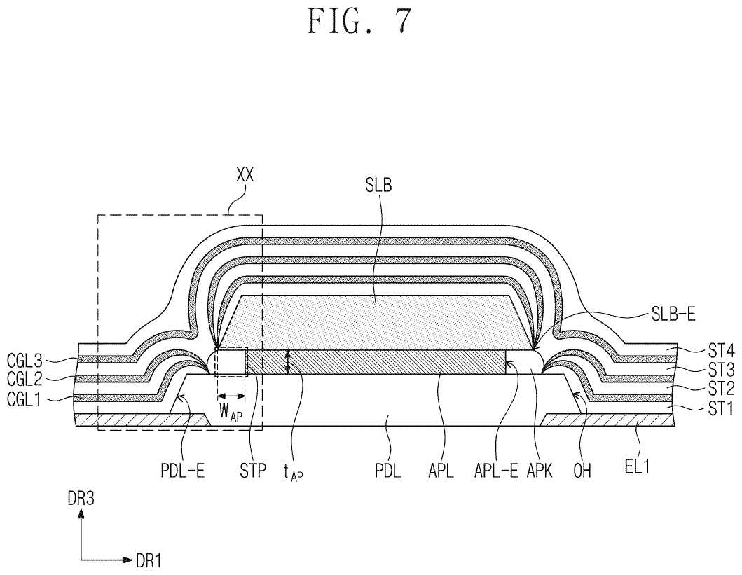

FIG. 7 is a cross-sectional view illustrating a portion of a display panel according to one or more embodiments. FIG. 8 is an enlarged cross-sectional view illustrating area XX in FIG. 7. FIGS. 7 and 8 selectively illustrate only some of components of the display layer illustrated in FIGS. 4 to 5C.

Referring to FIGS. 7 and 8, in the display panel according to one or more embodiments, an auxiliary layer APL and a separator SLB may overlap each other on a pixel-defining layer PDL. An edge SLB-E of the separator SLB may be exposed to a side of an emission opening portion OH, and the edge SLB-E of the separator SLB may further protrude to the side of the emission opening portion OH than an edge APL-E of the auxiliary layer APL.

A stepped space STP may be a space defined by a bottom surface BS-SLB of the separator SLB and a side surface of the auxiliary layer that is the edge APL-E of the auxiliary layer APL that is exposed to the side of the emission opening portion OH. The stepped space STP defined by the separator SLB and the auxiliary layer APL may have an undercut shape. That is, the separator SLB may include an area that does not overlap the auxiliary layer APL, so that a portion of the bottom surface thereof is exposed.

The auxiliary layer APL may have a thickness tap of about 100 Å to about 1000 Å. For example, the thickness t_{AP} of the auxiliary layer APL may be about 300 Å to about 500 Å. As the auxiliary layer APL has the thickness of about 100 Å to about 1000 Å, the stepped space STP may be stably defined when the separator SLB is provided. In addition, as the auxiliary layer APL has the thickness of about 100 Å to about 1000 Å, corrugation or folding of the encapsulation layer TFE (see FIG. 4) at a stepped space STP portion may be reduced or prevented.

The stepped space STP may have a width W_{AP} of about 0.5 μm or more. The width W_{AP} of the stepped space STP may correspond to a width of the portion of the bottom surface BS-SLB of the separator SLB that does not overlap the auxiliary layer APL and that is exposed. As the separator SLB is provided such that the width W_{AP} of the stepped space STP is about 0.5 μm or more, at least a portion of components of an emission unit may be disconnected in the stepped space STP, and corrugation or folding of the encapsulation layer TFE (see FIG. 4) at the stepped space STP portion may be reduced or prevented.

A side surface SS-SLB of the separator SLB may have a tilt angle θ of about 50 degrees to about 90 degrees. For example, the side surface SS-SLB of the separator SLB may have the tilt angle θ of about 55 degrees or more, thereby providing an undercut structure below the separator SLB so that a charge generation layer or the like is suitably disconnected. The tilt angle θ of the side surface SS-SLB of the separator SLB may be an angle based on the base substrate BS (see FIG. 4) on a cross-section defined by the first direction DR1 and the third direction DR3.

The tilt angle θ of the side surface SS-SLB of the separator SLB may be adjusted according to a change in process conditions when forming the separator SLB. The tilt angle θ, which is a taper angle, may be controlled by adjusting a curing process or the like after a resin for forming the separator SLB is provided.

At least one of charge generation layers CGL1, CGL2, or CGL3 may be disconnected in the stepped space STP. Referring to FIGS. 7 and 8, in one or more embodiments, among first to third charge generation layers CGL1, CGL2, and CGL3, the first charge generation layer CGL1 and the second charge generation layer CGL2 may be disconnected on the basis of the stepped space STP. In addition, the third charge generation layer CGL3 may remain connected to overlap the separator SLB, a first electrode EL1, and the like. However, FIGS. 7 and 8 are illustrative, and, unlike the illustrated embodiments, only the first charge generation layer CGL1 may be disconnected, or instead, all of the first to third charge generation layers CGL1, CGL2, and CGL3 may be disconnected and arranged.

Referring to FIGS. 7 and 8, at least one of emission structures ST1, ST2, ST3, or ST4 may be disconnected on the basis of the stepped space STP. In one or more embodiments, among first to fourth emission structures ST1, ST2, ST3, and ST4, the first emission structure ST1 and the second emission structure ST2 may be disconnected on the basis of the stepped space STP. In addition, the third emission structure ST3 and the fourth emission structure ST4 may be continuously connected to overlap the separator SLB, the first electrode EL1, and the like. However, FIGS. 7 and 8 are illustrative, and unlike the illustrated embodiments, only the first emission structure ST1 may be disconnected, or instead, the first to third emission structures ST1, ST2, and ST3, or even all of the first to fourth emission structures ST1, ST2, ST3, and ST4, may be disconnected and arranged. In addition, when the emission structure is disconnected, it is not limited to a case in which all of a hole transport region, an emission layer, and an electron transport region, which constitute the emission structure, are disconnected. For example, only a portion of the hole transport region, the emission layer, and the electron transport region, which constitute the emission structure, may be disconnected, and even in a case in which the emission structure is located without being disconnected, a portion of the hole transport region, the emission layer, and the electron transport region may be disconnected.

Among the components of the light-emitting element, only the charge generation layers CGL1, CGL2, and CGL3 may be disconnected in the stepped space STP, and the emission structures ST1, ST2, ST3, and ST4 may each be provided as a common layer without being disconnected.

Referring to FIGS. 7 and 8, in one or more embodiments, an air pocket APK may be defined by a space surrounded by a portion of the third emission structure ST3 of a light-emitting element LED, the edge APL-E of the auxiliary layer APL, a portion of the bottom surface BS-SLB of the separator SLB, and a portion of a top surface of the pixel-defining layer PDL that is exposed. The components of the light-emitting element LED might not be located in the air pocket APK. The air pocket APK may be an empty space in which the emission structures and the charge generation layers are not located. The air pocket APK may not be a completely sealed space, and a crack or a hole may have been generated in a portion of the components of the light-emitting element LED that define the air pocket APK.

In one or more embodiments, one end (e.g., one end of first portion CGL1-a) of the charge generation layer disconnected in the stepped space STP may be located on, or above, the pixel-defining layer PDL, and the other end (e.g., one end of second portion CGL1-b) thereof that is disconnected may be located on, or above, the separator SLB.

In one or more embodiments illustrated in FIGS. 7 and 8, the first charge generation layer CGL1 and the second charge generation layer CGL2 may include first portions CGL1-a and CGL2-a and second portions CGL1-b and CGL2-b, respectively, each of which being disconnected and separated. The first portions CGL1-a and CGL2-a may be located in the emission opening portion OH, and the second portions CGL1-b and CGL2-b thereof may be located at an upper side of the separator SLB.

In addition, the first emission structure ST1 and the second emission structure ST2 may include first portions ST1-a and ST2-a and second portions ST1-b and ST2-b, respectively, which may be disconnected and separated. One end of each of the first portions ST1-a and ST2-a may be located on or above the pixel-defining layer PDL, and one end of each of the second portions ST1-b and ST2-b may be located on or above the separator SLB. The first portions ST1-a and ST2-a of the first emission structure ST1 and the second emission structure ST2 may be located in the emission opening portion OH, and the second portions ST1-b and ST2-b thereof may be located at the upper side of the separator SLB. A crack CRL may be generated in the third emission structure ST3, the fourth emission structure ST4, and the third charge generation layer CGL3. The crack CRL may be generated by a bend generated due to the stepped space STP. Due to the crack CRL, each of the third emission structure ST3, the fourth emission structure ST4, and the third charge generation layer CGL3 may include a portion at which charge transfer or the like is not easily permitted.

The third emission structure ST3 and the fourth emission structure ST4 may include first portions ST3-a and ST4-a and second portions ST3-b and ST4-b, respectively, which are divided on the basis of the crack CRL. In addition, the third charge generation layer CGL3 may include a first portion CGL3-a and a second portion CGL3-b that are divided on the basis of the crack CRL.

FIG. 8 and the like illustrate the crack CRL generated in the entirety of the third emission structure ST3, the third charge generation layer CGL3, and the fourth emission structure ST4 to correspond to the disconnected portion, but one or more embodiments is not limited thereto. For example, the crack CRL may be generated in only a portion of the third emission structure ST3, the third charge generation layer CGL3, and/or the fourth emission structure ST4, or each of the third emission structure ST3, the third charge generation layer CGL3, and the fourth emission structure ST4 may be provided, without the crack CRL, as a common layer to the entirety of the emission areas.

In one or more embodiments, a portion of the charge generation layers CGL1, CGL2, and CGL3 may be disconnected in the stepped space STP, thereby reducing or preventing transfer of charges to neighboring emission areas along the charge generation layers. Accordingly, even in a case in which the emission unit EMU (see FIG. 4A) is provided as a common layer to the pixel areas PXA-R, PXA-G, and PXA-B (see FIG. 4A), transfer of charges or excitons in the emission unit EMU (see FIG. 4A) to adjacent pixel areas may be reduced or prevented, and thus, upon driving a selected emission area, generation of leakage emission may be reduced or prevented in adjacent emission areas.

That is, in the display panel according to one or more embodiments, the display layer may include the auxiliary layer and the separator that define the stepped space, thereby inducing a portion of the functional layers of the light-emitting element to be disconnected in the stepped space so that the undesired leakage emission in the emission area may be reduced or prevented to exhibit excellent display quality and color reproducibility.

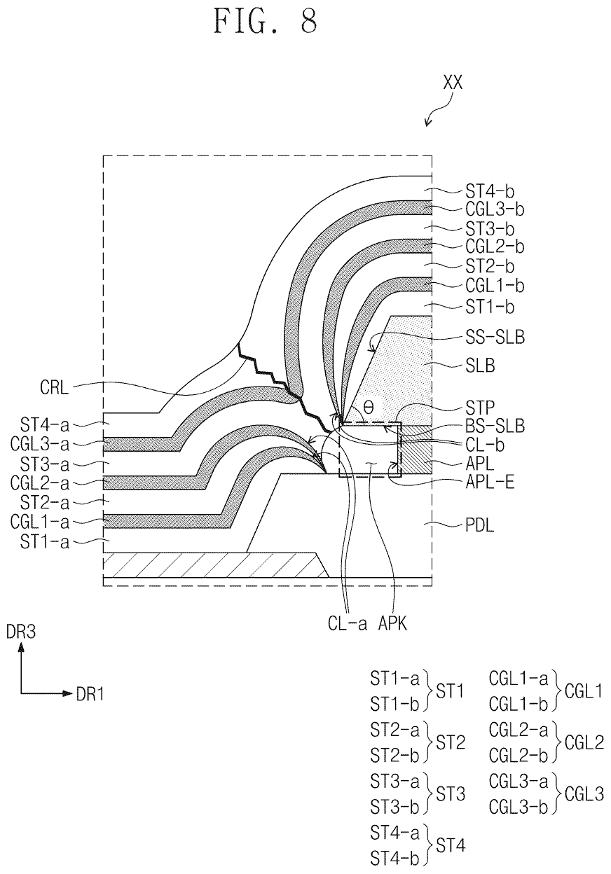

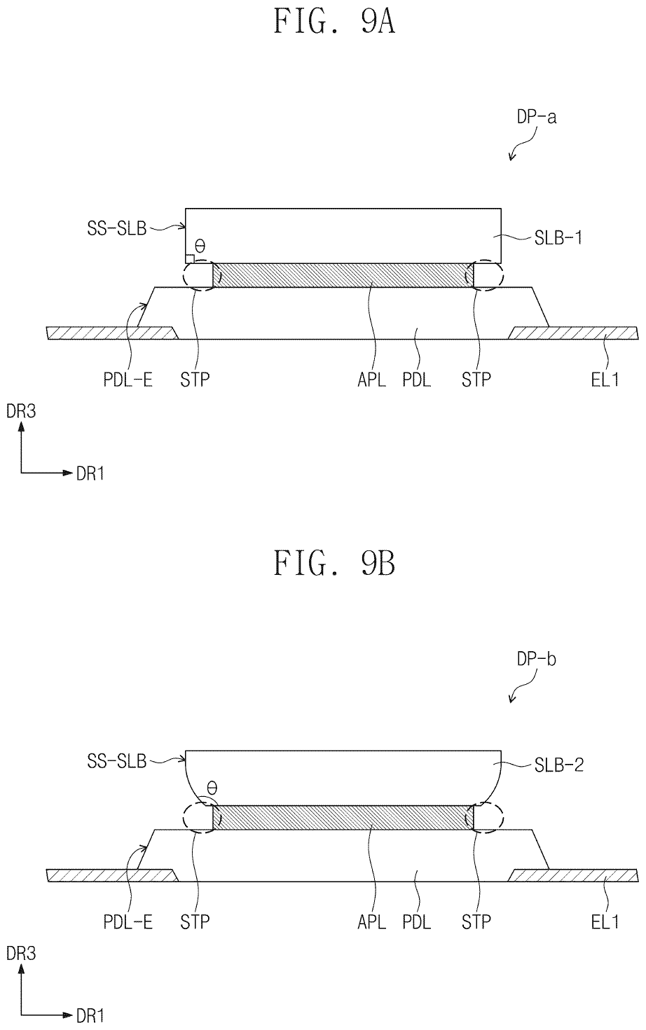

FIGS. 9A and 9B are each a view illustrating a portion of a display panel according to one or more embodiments. FIGS. 9A and 9B selectively illustrate only a stacked structure of an auxiliary layer APL and each of separators SLB-1 and SLB-2, which are located on a pixel-defining layer PDL.

Display panels DP-a and DP-b according to one or more embodiments illustrated in FIGS. 9A and 9B are different in terms of shapes of the separators from the display panel according to one or more embodiments described with reference to FIGS. 4 to 8. Referring to FIG. 9A, a tilt angle θ of a side surface SS-SLB of the separator SLB-1 may be about 90 degrees. Alternatively, in one or more embodiments, the tilt angle θ of the side surface SS-SLB of the separator SLB-1 may be more than about 90 degrees, and the separator SLB-1 may have a reverse tapered shape on a cross-section.

Referring to FIG. 9B, a side surface SS-SLB of the separator SLB-2 may include a curved surface, and a tilt angle θ of the side surface SS-SLB may be more than about 90 degrees. Here, the tilt angle θ of the side surface SS-SLB may be a tilt angle formed by a tangent of the side surface SS-SLB.

Also, in one or more embodiments in FIGS. 9A and 9B, a stepped space STP may be defined between each of the separators SLB-1 and SLB-2 and the auxiliary layer APL. As described with reference to FIGS. 4 to 8, a portion of functional layers of a light-emitting element may be disconnected in the stepped space STP.

In one or more embodiments, the tilt angle θ of the side surface SS-SLB of the separator SLB-1 may be more than about 90 degrees, and the separator SLB-1 may have a reverse tapered shape on a cross-section.

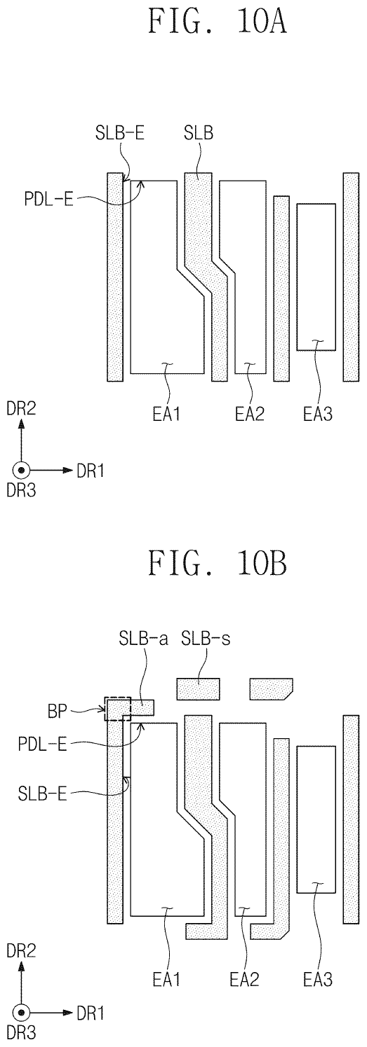

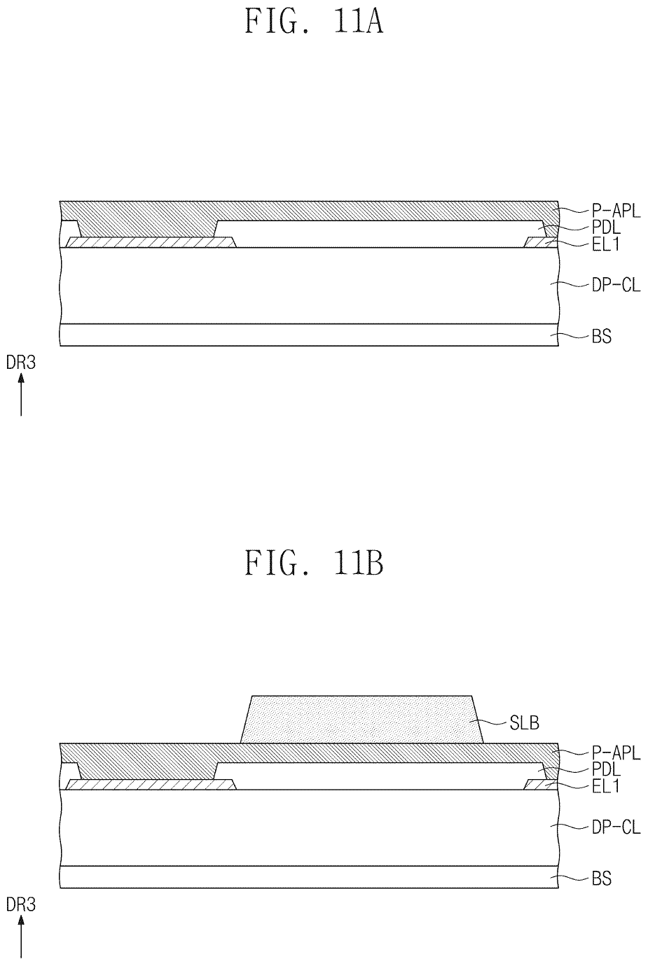

FIGS. 10A and 10B are each a plan view illustrating a portion of a display panel according to one or more embodiments. As an example, FIGS. 10A and 10B each illustrate a planar arrangement shape of emission areas and a separator.

Referring to FIGS. 10A and 10B, the display panel may include a first emission area EA1, a second emission area EA2, and a third emission area EA3, which are located on a plane defined by the first direction DR1 and the second direction DR2 and spaced apart from each other in the first direction DR1. Planar shapes of the first emission area EA1, the second emission area EA2, and the third emission area EA3 illustrated in FIGS. 10A and 10B may correspond to the first pixel area PXA-R, the second pixel area PXA-G, and the third pixel area PXA-B, respectively, which are described with reference to FIG. 3.

An edge of each of the emission areas EA1, EA2, and EA3 may be defined as an edge PDL-E of a pixel-defining layer. Each of the emission areas EA1, EA2, and EA3 may be an area located inside the pixel-defining layer, and an area surrounded by the edge PDL-E of the pixel-defining layer.

On a plane, each of the emission areas EA1, EA2, and EA3 may have a polygonal shape having a short side extending in the first direction, and a long side extending in the second direction crossing the first direction.

Referring to FIG. 10A, a separator SLB may have a shape extending in the second direction DR2 between emission areas adjacent to each other in the first direction DR1 among the emission areas EA1, EA2, and EA3. The separator SLB may not be connected to another separator (e.g., may be separated from other separators), and may correspond to each of a space between the first emission area EA1 and the second emission area EA2, a space between the second emission area EA2 and the third emission area EA3, a space at one side of the first emission area EA1, and a space at one side of the third emission area EA3.

A planar shape of the separator SLB may correspond to a shape of an area between the emission areas EA1, EA2, and EA3 located spaced apart from each other in the first direction DR1 with the separator SLB therebetween. However, one or more embodiments is not limited thereto, and the separator SLB may be applied without limitation as long as having a shape that has a sufficient length to separate adjacent emission areas from each other between the emission areas respectively corresponding to pixel areas that emit light in different wavelength regions.

The separator SLB may sufficiently reduce or prevent contact between respective side surfaces of adjacent emission areas in the emission areas EA1, EA2, and EA3 arranged in the first direction DR1, and also, as being located to correspond to each of the spaces between the emission areas EA1, EA2, and EA3, the separator SLB may disconnect at least a portion of components of a light-emitting element, each of that is provided as a common layer to the emission areas EA1, EA2, and EA3. Accordingly, leakage emission that is generated due to an influence of emission areas adjacent in the first direction DR1 that is a lateral direction may be reduced.

In addition, as the separator SLB is located to correspond to each of the spaces between the adjacent emission areas EA1, EA2, and EA3, the separator SLB may absorb part of light that is emitted by the emission areas EA1, EA2, and EA3 at the side surface without being parallel to a front direction (the third direction DR3). Accordingly, color mixture between the pixel areas that emit light in different wavelength regions may be reduced or prevented to improve a degree of color matching and color reproducibility.

FIG. 10B illustrates one or more embodiments that are different from the one or more embodiments in FIG. 10A in terms of an arrangement and a shape of a separator. In one or more embodiments, the separator may include a main portion SLB-a, which is located in each of spaces between the emission areas EA1, EA2, and EA3 adjacent to each other in the first direction DR1, and may also include a secondary portion SLB-s that is spaced apart from the main portion SLB-a and spaced apart from at least one of the emission areas EA1, EA2, or EA3 in the second direction DR2. In one or more embodiments, the separators of the main portion SLB-a and the secondary portion SLB-s may be spaced apart from each other.

In addition, the main portion SLB-a of the separator may include a bending portion BP having a shape surrounding at least a portion of corners of the emission areas EA1, EA2, and EA3.

FIGS. 10A and 10B illustrate examples of the planar shape of the separator, and the present disclosure is not limited thereto. The planar shape of the separator may be changed according to planer shapes of the emission areas, an arrangement shape of the emission areas, an arrangement gap between the emission areas, and the like.

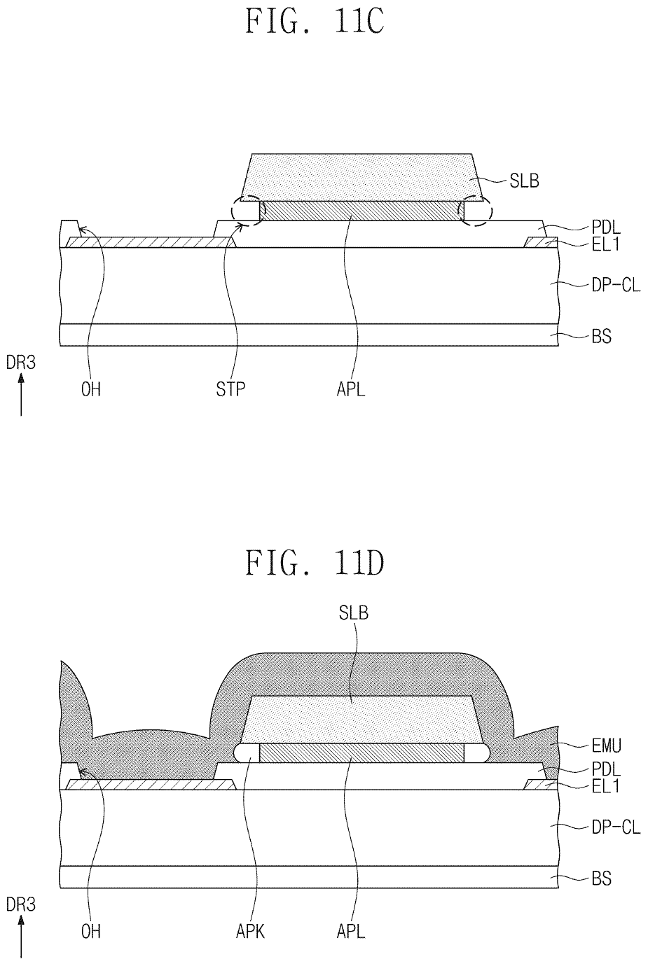

FIGS. 11A to 11D are each a view illustrating one operation of a method for manufacturing a display panel according to one or more embodiments. As an example, FIGS. 11A to 11D each illustrate one operation of manufacturing a display layer in the display panel according to one or more embodiments.

Referring to FIG. 11A, a preliminary auxiliary layer P-APL may be provided on a stacked structure of a base substrate BS and a circuit layer DP-CL. The preliminary auxiliary layer P-APL may cover the entirety of a pixel-defining layer PDL and a first electrode EL1. That is, the preliminary auxiliary layer P-APL may be entirely deposited onto the circuit layer DP-CL. A transparent conductive oxide material may be deposited to form the preliminary auxiliary layer P-APL.

Referring to FIG. 11B, a separator SLB may be formed on the preliminary auxiliary layer P-APL. The separator SLB may be formed as an organic film including a black component. The separator SLB may be formed through a patterning process using coating with a resin composition and ultraviolet curing. A thickness, a taper angle, and the like of the separator SLB may be adjusted by controlling process conditions of the patterning process, such as ultraviolet curing.

FIG. 11C illustrates an operation of forming a stepped space STP below the separator SLB. The stepped space STP may correspond to a space defined above the pixel-defining layer PDL by a portion of a bottom surface of the separator SLB and a side surface of an auxiliary layer APL (and, for example, a portion of a top surface of the pixel-defining layer).

The stepped space STP may be defined by etching the preliminary auxiliary layer P-APL through wet etching after the forming of the separator SLB to form the preliminary auxiliary layer P-APL as the auxiliary layer APL. The stepped space STP may be a portion that is defined to have an undercut shape, as a side surface of the separator SLB and the side surface of the auxiliary layer APL do not overlap each other. The preliminary auxiliary layer P-APL may be formed of the transparent conductive oxide material that is crystallized at a temperature of about 260° C. or more, thereby increasing selectivity of the preliminary auxiliary layer in the wet etching. Accordingly, the stepped space STP having the undercut shape may be defined.

FIG. 11D illustrates an operation of providing an emission unit. An emission unit EMU may cover the entirety of an emission opening portion OH and the separator SLB. At least a portion of the emission unit EMU may be disconnected in the stepped space STP, and an air pocket APK, which is surrounded by a portion of the emission unit EMU, a portion of the bottom surface of the separator SLB, an edge of the auxiliary layer APL, and a portion of a top surface of the pixel-defining layer PDL, may be formed in the stepped space STP.

In one or more embodiments, a second electrode, a capping layer, an encapsulation layer, and the like may be provided in sequence on the emission unit EMU, thereby manufacturing the display panel.

Table 1 shows display quality evaluation results for Example (e.g., an example of one or more embodiments of the present disclosure) and Comparative Examples 1 and 2. In Table 1, color reproducibility was evaluated based on a CIE 1976 color coordinate system. In luminance and gray crushing, the luminance and the gray crushing in mono-color emission of each of a red color (R), a green color (G), and a blue color (B) were evaluated, and may be defined by Equation 1 below.

$$Gray Crushing = Measured luminance / Target luminance \qquad Equation 1$$

In Table 1, the gray crushing corresponds to a ratio of leakage luminance for each of the red color (R), the green color (G), and the blue color (B) in a case in which a white color has a luminance of about 0.4 nit.

Parasitic emission is obtained by evaluating a luminance variation due to parasitic current. In Table 1, the parasitic emission indicates luminance variations when parasitic currents are about 0.4 nit and about 1.0 nit with respect to a case in which white light luminance is about 100 nit.

Low-grayscale overshoot is obtained by evaluation of a phenomenon in which, when a low-grayscale is implemented, the luminance is unexpectedly increased. FFR represents a ratio of a luminance of a first frame to a saturation (Sat. frame) luminance. Table 1 shows all items for the bottom 20% of the display quality as low-grayscale overshoot evaluation items, and results of evaluating the low-grayscale overshoot of each of the red color (R), the green color (G), and the blue color (B).

Table 1 show results of evaluating FFR by dividing a section in which the luminance is about 1 nit to about 100 nit, and a section in which the luminance is about 0.026 nit to about 1 nit.

In addition, in Table 1, Comparative Example 1 corresponds to a display panel in which both an auxiliary layer and a separator are not located on a pixel-defining layer, and Comparative Example 2 corresponds to a display panel in which a separator is directly located, without an auxiliary layer, on a pixel-defining layer. Example corresponds to a display panel including a light-emitting element that includes the stacked structure of the auxiliary layer and the separator illustrated I FIG. 4 and induces a disconnection. The display panel according to each of Comparative Example 1, Comparative Example 2, and Example evaluated in Table 1 below corresponds to a 27″ display panel having a resolution of about 160 ppi.

TABLE 1

| | | | Comparative | Comparative | |
|---|---|---|---|---|---|
| Item | | Unit | Example 1 | Example 2 | Example |
| Color reproducibility | | % | 98.7 | 99.5 | 99.4 |
| Gray crushing | | % | 65.0/ | 91.3/ | 89.8/ |
| (R/G/B) | | | 55.9/75.6 | 84.3/86.2 | 85.8/94.3 |
| Parasitic | 0.4 nit | Δuv | 0.045/ | 0.022/ | 0.013/ |
| emission | | | 0.007/0.034 | 0.003/0.018 | 0.001/0.013 |
| (based on | 1.0 nit | Δuv | 0.063/ | 0.020/ | 0.016/ |
| white light | | | 0.013/0.046 | 0.003/0.016 | 0.002/0.015 |
| 100 nit) | | | | | |
| (R/G/B) | | | | | |
| Low- | All | % | 928 | 423 | 150 |
| grayscale | items | | | | |
| overshoot | R/G/B | % | 599/360/449 | 267/329/166 | 106/85/129 |
| FFR | 1-100 | % | 63.7 | 80.5 | 85.4 |
| | nit | | | | |
| | 0.026- | % | 26.4 | 68.8 | 74.2 |
| | 1 nit | | | | |

Referring to the results in Table 1, it may be confirmed that Example (e.g., according to one or more embodiments of the present disclosure) exhibits more excellent color reproducibility than Comparative Example 1. It may be confirmed that Example was reduced in luminance variation due to the parasitic emission compared to Comparative Examples 1 and 2. It may be also seen that Example was significantly improved in low-grayscale overshoot compared to Comparative Examples 1 and 2. With regard to FFR, it may be confirmed that Example showed a bigger value than Comparative Examples.

Based on the results in Table 1, it may be confirmed that compared to Comparative Examples 1 and 2, Example showed the excellent color reproducibility and was improved in image characteristics generated due to the leakage emission.

In a display panel and an electronic device according to one or more embodiments, a display layer may include an auxiliary layer and a separator that define a stepped space, thereby disconnecting a portion of components of a light-emitting element on the basis of the stepped space. Accordingly, leakage emission due to neighboring emission areas may be reduced or minimized. In addition, the display panel and the electronic device according to one or more embodiments may include the separator including a black component, thereby absorbing light provided in a lateral direction. Accordingly, the display panel and the electronic device according to one or more embodiments may be improved in color matching ratio and color reproducibility, and exhibit excellent display quality with reduced reflected light.

The display panel according to the disclosed embodiments may include the separator that is located on the pixel-defining layer and defines the stepped space, thereby disconnecting the portion of the common layers of the light-emitting element on the basis of the stepped space. Accordingly, the leakage emission in the neighboring emission area direction may be reduced to exhibit the excellent display quality.

The electronic device according to the disclosed embodiments may include the separator that defines the stepped space that disconnects the portion of the common layers of the light-emitting element, thereby reducing the leakage emission between the adjacent pixel areas, which emit the light in the different wavelength regions, to exhibit the excellent display quality even at the high resolution.

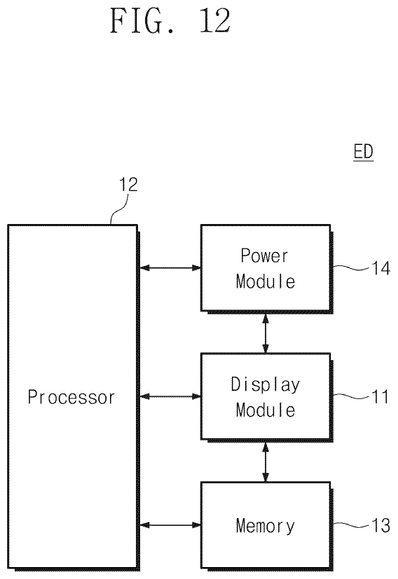

FIG. 12 is a block diagram of an electronic device according to an embodiment. Referring to FIG. 12, an electronic device ED according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 15 may store data information necessary for an operation of the processor 12 or the display module 11. When the processor 12 executes an application stored in the memory 15, an image data signal and/or an input control signal may be transmitted to the display module 11, and the display module 11 may process the received signal and output image information through a display screen. The display module 11 may include a display panel which displays an image.

The power module 14 may include a power supply module such as a power adapter or a battery device, and a power conversion module which converts the power supplied by the power supply module and generates power necessary for an operation of the electronic device ED.

At least one of the components of the electronic device ED described above may be included in a display device including the display panel according to an embodiment, described later. In addition, some of individual modules included as functional in one module may be included in the display device, and others may be provided separately from the display device. For example, the display device may include the display module 11, and the processor 12, the memory 13, and the power module 14 may be provided not in the display device but in another type of device in the electronic device ED.

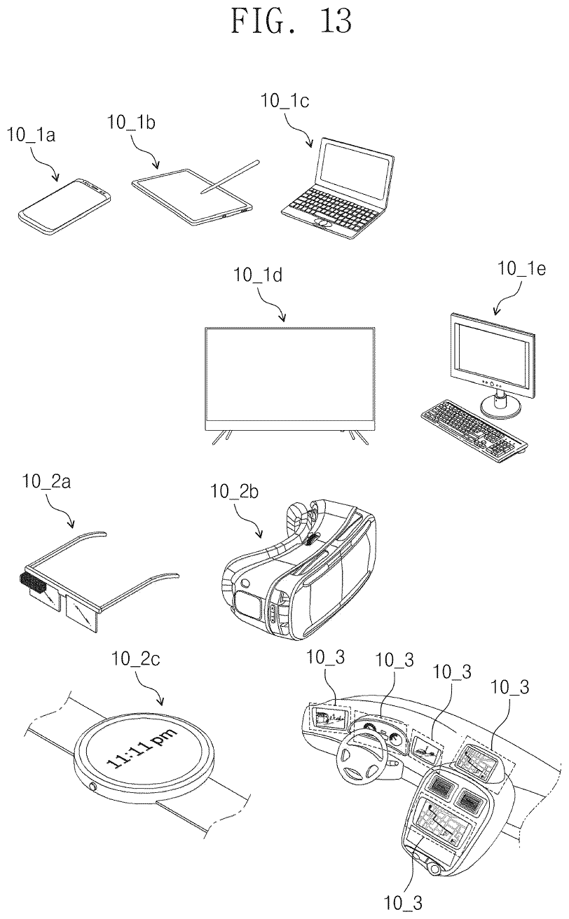

FIG. 13 illustrates schematic views of electronic devices according to various embodiments.

Referring to FIG. 13, various electronic devices including a display device according to an embodiment may include not only an electronic device for image display, e.g., a smartphone 10_1a, a tablet computer (PC) 10_1b, a laptop computer 10_1c, TV 10_1d, and a monitor for a desk computer 10_1e, but also a wearable electronic device including a display module, e.g., smart glasses 10_2a, a head mounted display 10_2b, and a smart watch 10_2c, and an electronic device for vehicle 10_3 including a display module, e.g., a vehicle instrument panel, a center fascia, a center information display (CID) disposed on a dashboard, and a room mirror display.

Although the embodiments have been described, it is understood that the present disclosure should not be limited to these embodiments but various changes and modifications can be made by one ordinary skilled in the art within the spirit and scope of the present disclosure.

Therefore, the technical scope of the present disclosure is not limited to the contents described in the detailed description of the specification, but should be determined by the claims, with functional equivalents thereof to be included therein.

What is claimed is:

1. A display panel comprising:
a base substrate;
a circuit layer above the base substrate, and comprising a transistor;
a pixel-defining layer above the circuit layer, and defining an emission opening portion;
an auxiliary layer above the pixel-defining layer, and comprising a transparent metal oxide;
a separator above the auxiliary layer, comprising a black component, and having an edge protruding toward the emission opening portion further than an edge of the auxiliary layer; and
a light-emitting element above the circuit layer, and comprising a first electrode in the emission opening portion, a second electrode facing the first electrode, emission structures between the first electrode and the second electrode, and charge generation layers between the first electrode and the second electrode,
wherein a stepped space is defined by a portion of a bottom surface of the separator, the edge of the auxiliary layer, and a portion of an upper surface of the pixel-defining layer, and
wherein at least one of the charge generation layers is disconnected at the stepped space.

2. The display panel of claim 1, further comprising an air pocket in the stepped space at which the emission structures and the charge generation layers are discontinuous.

3. The display panel of claim 1, wherein the at least one of the charge generation layers comprises one end above the pixel-defining layer, and another end above the separator.

4. The display panel of claim 1, wherein the emission structures comprise a first emission structure, a second emission structure, a third emission structure, and a fourth emission structure, stacked in a thickness direction and comprising an emission layer,
wherein the charge generation layers comprise a first charge generation layer between the first emission structure and the second emission structure, a second charge generation layer between the second emission structure and the third emission structure, and a third charge generation layer between the third emission structure and the fourth emission structure, and
wherein at least one of the first emission structure, the second emission structure, the third emission structure, or the fourth emission structure and at least one of the first charge generation layer, the second charge generation layer, or the third charge generation layer are disconnected at the stepped space.

5. The display panel of claim 1, wherein the separator comprises an organic film comprising the black component.

6. The display panel of claim 1, wherein the separator overlaps only a partial area of the pixel-defining layer.

7. The display panel of claim 1, wherein the auxiliary layer comprises:
a transparent conductive oxide material that is crystallized at a temperature of about 260° C. or more; and
an indium gallium zinc oxide (IGZO) or an indium zinc oxide (IZO) having a weight ratio of indium to zinc of about 9:1 to about 1:1.

8. The display panel of claim 1, wherein a thickness of the auxiliary layer is about 100 Å to about 1000 Å.

9. The display panel of claim 1, wherein a tilt angle of a side surface of the separator to the base substrate is about 50 degrees to about 90 degrees.

10. The display panel of claim 1, wherein the transistor comprises a semiconductor pattern comprising a metal oxide comprising at least one of indium, gallium, zinc, tin, or titanium divided into an active, a source, and a drain, and a gate above the semiconductor pattern.

11. A display panel comprising:
a base substrate;
a circuit layer above the base substrate, and comprising a transistor; and
a display layer above the circuit layer, defining emission areas separated from each other, and comprising:
a pixel-defining layer above the circuit layer, and defining an emission opening portion corresponding to the emission areas;
an auxiliary layer above the pixel-defining layer, and comprising a transparent metal oxide;
a separator above the auxiliary layer, comprising a black component, and having an edge protruding further toward the emission opening portion than an edge of the auxiliary layer; and
a light-emitting element above the circuit layer, and comprising a first electrode, a second electrode facing the first electrode, emission structures between the first electrode and the second electrode, and charge generation layers between the first electrode and the second electrode,
wherein a stepped space having an undercut shape is defined by a portion of a bottom surface of the separator, the edge of the auxiliary layer, and a portion of an upper surface of the pixel-defining layer, and
wherein at least one of the charge generation layers is disconnected at the stepped space.

12. The display panel of claim 11, wherein, on a plane, the emission areas have a polygonal shape having a short side extending in a first direction, and a long side extending in a second direction crossing the first direction, and
wherein the separator has a shape extending in the second direction between adjacent ones of the emission areas adjacent to each other in the first direction, and comprises:
a main portion between the adjacent ones of the emission areas;
a secondary portion spaced apart from the main portion, and spaced apart from at least one of the adjacent ones of the emission areas in the second direction; or
a bending portion having a shape surrounding at least a portion of a corner of the at least one of the adjacent ones of the emission areas.

13. The display panel of claim 11, wherein the separator comprises an organic film comprising the black component.

14. The display panel of claim 11, wherein the auxiliary layer comprises an indium zinc oxide having a weight ratio of indium to zinc of about 9:1 to about 1:1.

15. The display panel of claim 11, wherein the emission structures comprise at least one green emission structure and at least one blue emission structure.

16. An electronic device comprising:
a display panel comprising a first emission area, a second emission area, and a third emission area spaced apart on a plane, sequentially arranged in a first direction, and configured to emit source light; and
a light control panel above the display panel, and configured to transmit the source light or to convert a wavelength of the source light,
wherein the display panel comprises:
a base substrate;
a circuit layer above the base substrate, and comprising a transistor;
a pixel-defining layer above the circuit layer, and defining an emission opening portion;
an auxiliary layer above the pixel-defining layer, and comprising a transparent metal oxide;
a separator above the auxiliary layer, comprising a black component, and having an edge protruding further toward the emission opening portion than an edge of the auxiliary layer; and
a light-emitting element above the circuit layer, and comprising a first electrode in the emission opening portion, a second electrode facing the first electrode, emission structures between the first electrode and the second electrode, and charge generation layers between the first electrode and the second electrode,
wherein a stepped space is defined by a portion of a bottom surface of the separator, the edge of the auxiliary layer, and a portion of an upper surface of the pixel-defining layer, and
wherein at least one of the charge generation layers is disconnected at the stepped space.

17. The electronic device of claim 16, further comprising at least one of a processor, a memory, or a power module.

18. The electronic device of claim 16, wherein the electronic device is an image display device, a wearable device, or a device for vehicle.

19. The electronic device of claim 16, further comprising an air pocket in the stepped space at which the emission structures and the charge generation layers are discontinuous,
wherein the at least one of the charge generation layers comprises one end above the pixel-defining layer, and another end above the separator.

20. The electronic device of claim 16, wherein the separator comprises an organic film comprising the black component, and
wherein the separator is provided in plural to be respectively in spaces respectively between the first emission area and the second emission area, and between the second emission area and the third emission area.
